(19) United States
(12) Patent Application Publication
(10) Pub. No.: US 2010/0319759 A1
(43) Pub. Date: Dec. 23, 2010

(54) NANOSTRUCTURE AND METHODS OF MAKING THE SAME

(76) Inventors: John Fisher, Folsom, CA (US); Larry Bawden, El Dorado Hills, CA (US); Vincent Evelsizer, Folsom, CA (US); Brian Argo, Greenville, WI (US); John Argo, West Sacramento, CA (US); Ruxandra Vidu, Citrus Heights, CA (US)

Correspondence Address: Zilka-Kotab, PC, P.O. BOX 721120, SAN JOSE, CA, 95172-1120, US

(21) Appl. No.: 12/820,842

(22) Filed: Jun. 22, 2010

Related U.S. Application Data
(60) Provisional application No. 61/219,277, filed on Jun. 22, 2009.

(51) Int. Cl. H01L 31/02; H01L 31/18

(52) U.S. Cl. 136/252; 438/64; 977/762; 257/E31.033

(57) ABSTRACT

Nanostructures and photovoltaic structures are disclosed. Method for creating nanostructures are also presented. A method according to one embodiment includes adding a template to a substrate; depositing conductive material in the template thereby forming an array of conductive nanocables on the substrate; removing at least part of the template; and depositing at least one layer of photovoltaic material on exposed portions of the conductive nanocables. A nanostructure according to one embodiment includes an array of nanocables extending from a substrate, the array of nanocables having physical characteristics of having been formed using an at least partially removed template; an insulating layer extending along the substrate; and at least one layer of photovoltaic material overlaying portions of the nanocables.

### RELATED APPLICATIONS

This application claims priority to U.S. Provisional Patent Application No. 61/219,277 filed Jun. 22, 2009, and which is herein incorporated by reference.

### FIELD OF INVENTION

This invention pertains generally to nanotechnology and particularly to nano-scale structures and processes for making these structures.

### BACKGROUND

Solar panels that harness solar energy and convert it to electrical energy are well known. A typical solar electricity system includes the following components: solar panels, charge controller, inverter, and often batteries. A typical solar panel, often referred to as a photovoltaic (PV) module, consists of a one or more interconnected PV cells environmentally sealed in protective packaging consisting of a glass cover and extruded aluminum casing.

The PV cell may be a p-n junction diode capable of generating electricity in the presence of sunlight. It is often made of crystalline silicon (e.g., polycrystalline silicon) doped with elements from either group 13 (group III) or group 15 (group V) on the periodic table. When these dopant atoms are added to the silicon, they take the place of silicon atoms in the crystalline lattice and bond with the neighboring silicon atoms in almost the same way as the silicon atom that was originally there. However, because these dopants do not have the same number of valence electrons as silicon atoms, extra electrons or “holes” become present in the crystal lattice. Upon absorbing a photon that carries an energy that is at least the same as the band gap energy of the silicon, the electrons become free. The electrons and holes freely move around within the solid silicon material, making silicon conductive. The closer the absorption event is to the p-n junction, the greater the mobility of the electron-hole pair.

When a photon that has less energy than silicon's band gap energy strikes the crystalline structure, the electrons and holes are not mobilized. Instead of the photon's energy becoming absorbed by the electrons and holes, the difference between the amount of energy carried by the photon and the band gap energy is converted to heat.

While the idea of converting solar energy to electrical power has much appeal, conventional solar panels have limited usage because their efficiencies are generally only around 15% and are manufactured using costly silicon wafer manufacturing processes and materials. This low efficiency is due in part to the planar configuration of current PV cells, as well as the relatively large distances between the electrodes and the P-N junction. Low efficiency means that larger and heavier arrays are needed to obtain a certain amount of electricity, raising the cost of a solar panel and limiting its use in large-scale structures.

The most common material for solar cells is silicon. Crystalline silicon generally comes in three categories: single-crystal silicon, polycrystalline silicon, and ribbon silicon. Solar cells made with single or monocrystalline wafers have the highest efficiency of the three, at about 20%. Unfortunately, single crystal cells are expensive and round so they do not completely tile a module. Polycrystalline silicon is made from cast ingots. They are typically made by filling a large crucible with molten silicon and carefully cooling and solidifying them. The polycrystalline silicon is less expensive than single crystal, but is only about 10-14% efficient depending on the process conditions and resulting imperfections in the material. Ribbon silicon is the last major category of PV grade silicon. It is typically formed by drawing flat, thin films from molten silicon, and has a polycrystalline structure. Silicon ribbon's efficiency range of 11-13% is also lower than monocrystalline silicon due to more imperfections. Most of these technologies are based on wafers about 300 μm thick. The PV cells are fabricated then soldered together to form a module.

Another technology under development is multijunction solar cells, which is expected to deliver less than 18.5% efficiency in actual use. The process and materials to produce multijunction cells are enormously expensive. Those cells require multiple gallium/indium/arsenide layers. The best is believed to be a sextuple-junction cell. Current multijunction cells cannot be made economical for large-scale applications.

A promising enabler of PV cells and other technology is nanotechnology. However, one problem with implementing nanotechnology is that the minute conductors may not be able to withstand their own formation, much less subsequent processing conditions or conditions of use in the end product. For example, the metal forming the nanoconductors may be soft, making it prone to bending or breaking during application of additional layers.

Further, it has heretofore proven difficult and even impossible to create nanoarrays having structures of uniform size and/or spacing.

Thus, as alluded to, the technology available to create PV cells and other electronic structures is limited to some extent by processing limitations as well as the sheer fragileness of the structures themselves.

Therefore, it would be desirable to enable creation of nanostructures having high aspect ratios and yet are durable enough for practical use in industry.

It would also be desirable to enable fabrication of a solar cell that has a higher than average efficiency, and in some embodiments, higher than about 30%.

### SUMMARY

A method according to one embodiment includes adding a template to a substrate; depositing conductive material in the template thereby forming an array of conductive nanocables on the substrate; removing at least part of the template; and depositing at least one layer of photovoltaic material on exposed portions of the conductive nanocables.

A nanostructure according to one embodiment includes an array of nanocables extending from a substrate, the array of nanocables having physical characteristics of having been formed using an at least partially removed template; an insulating layer extending along the substrate; and at least one layer of photovoltaic material overlaying portions of the nanocables.

In one approach, the template is created by forming a membrane on a patterned surface, and removing the membrane from the patterned surface, wherein the membrane is subsequently coupled to the substrate for being the template. The membrane may include a dielectric, polymer or a combination thereof.

In one approach, the template is formed by embossing. In another approach, the template is added to the substrate in a continuous process. In yet another approach, the template is formed at least in part from a photoresist that is patterned without a hard mask.

The at least one layer of photovoltaic material may be electroplated, formed by chemical vapor deposition and etching, and/or any suitable process. In one embodiment, depositing one of the layers of photovoltaic material includes performing multiple chemical bath depositions with at least one of a thermal anneal and a densification performed between the chemical bath depositions.

The nanocables, or groups thereof, may be elongated, and may have substantially uniform peripheries. Axes of the nanocables are tilted from a direction normal to a plane of the substrate in some embodiments.

In one embodiment, a first group of the nanocables has a different composition, thickness, and/or height than a second group of the nanocables. In another embodiment, the at least one layer of photovoltaic material overlaying a first group of the nanocables has a different composition and/or thickness than the at least one layer of photovoltaic material overlaying a second group of the nanocables.

The template may partially remain during the deposition of the at least one layer of photovoltaic material. At least a portion of the template may remain in the final structure as an insulating layer.

In one embodiment, the substrate is electrically conductive, and at least a portion of the conductive substrate is segmented for forming electrically isolated segments thereof. In one approach, in a first deposition, electricity is conducted only to a first group of the conductive nanocables for depositing the at least one layer of photovoltaic material thereon; wherein in a second deposition, electricity is conducted only to a second group of the conductive nanocables for depositing the at least one layer of photovoltaic material thereon; wherein the first and second groups include at least some different conductive nanocables. As a result, a composition, thickness, and/or height of structures formed by the first deposition may be different than a composition, thickness, and/or height of structures formed in the second deposition.

In one embodiment, the substrate is conductive, and is treated for enhancing electrical contact between the substrate and the conductive nanocables.

A front contact in communication with an uppermost of the at least one layer of photovoltaic material may be created.

In another embodiment, a conductive layer is formed over the at least one layer of photovoltaic material, and is segmented into electrically isolated segments.

In one embodiment, the array of conductive nanocables with photovoltaic material thereon may be coupled to another photovoltaic device, the photovoltaic device being at least semi-transparent, wherein the array is positioned relative to the photovoltaic device such that light passing through the photovoltaic device strikes the array.

In another embodiment, at least some of the conductive nanocables with photovoltaic material thereon have a portion with a wider diameter than in another portion thereof. The portion having the wider diameter may be positioned towards the substrate or away from the substrate.

In one embodiment, a dielectric overcoat, e.g., of ethyl vinyl acetate may be deposited over the structure.

One embodiment includes photovoltaically activating the conductive nanocables with photovoltaic material thereon using a pulsating laser. In another embodiment, a layer is deposited over the nanocables, wherein a material of the layer is of sufficient temperature at deposition thereof to photovoltaically activate the nanocables with the at least one layer of photovoltaic material thereon. In one approach, the layer is a transparent conductive oxide that also acts as a front contact for the nanocables with photovoltaic material thereon.

Voids are present in the array in one embodiment. A conductive layer is formed over the array and a conductor is coupled to the conductive layer in the void.

### BRIEF DESCRIPTION OF THE DRAWINGS

FIG. 1 is a perspective view of an exemplary solar brush that may be used to implement solar panels with improved efficiency.

FIG. 2 is a side cross-section of the solar brush.

FIGS. 3A and 3B are cross-sectional views of embodiments of the solar brush having a layered structure.

FIG. 3C is a cross-sectional view of a solar brush embodiment employing a thin film planar device as a filter.

FIG. 4 is a top view of the solar brush showing the tops of the bristles.

FIGS. 5A-5H illustrate an exemplary method for fabricating the solar brush.

FIGS. 6A-6F illustrate an alternative method for fabricating the solar brush.

FIGS. 7A-7H illustrate a dimension-controlling process for forming the nanocables.

FIG. 8 is a flowchart summarizing the steps of the dimension-controlling process of FIGS. 7A-7H.

FIGS. 9A-9I illustrate the carbon jacket process for producing organic nanocables.

FIGS. 10A-E illustrate the insulator etching process.

FIG. 11 shows the solar brush encapsulated in an optical casing for protection.

FIG. 12 is a graph showing a potential power generation for a planar solar cell.

FIG. 13 is a top partial cross sectional view of the solar brush showing an array of bristles and a conductor in a void in the array.

### DETAILED DESCRIPTION

The following description is the best mode presently contemplated for carrying out the present invention. This description is made for the purpose of illustrating the general principles of the present invention and is not meant to limit the inventive concepts claimed herein. Further, particular features described herein can be used in combination with other described features in each and any of the various possible combinations and permutations.

Unless otherwise specifically defined herein, all terms are to be given their broadest possible interpretation including meanings implied from the specification as well as meanings understood by those skilled in the art and/or as defined in dictionaries, treatises, etc.

It must also be noted that, as used in the specification and the appended claims, the singular forms “a,” “an” and “the” include plural referents unless otherwise specified.

Embodiments of the invention are described herein in the context of solar cells. However, it is to be understood that the particular application provided herein is just an exemplary application, and the nanocable arrangement of the invention is not limited to the application or the embodiments disclosed herein.

This disclosure also relates to nano arrays of thin film solar cells. Solar modules constructed using thin film systems tend to use a single larger single plane thin films solar cell, rather than an array of smaller interconnected nano-scale solar cells. The entire module can use a laser scribe to mark individual cells. It is important to note that nano systems will be processed differently than current technology thin films. Four main thin film material system types are amorphous silicon (A-Si), copper indium selenide (CuInSe₂ commonly referred to as CIS), copper indium gallium selenide (CuInₓGa₁₋ₓSeₓ) commonly referred to as CIGS), and CdTe/CdS. A-Si films are typically fabricated using plasma enhanced chemical vapor deposition (PE-CVD).

The term “nanocable” denotes any elongated body whose one dimension (e.g., diameter or width) is of nano or micro scale or size and the other dimension is larger, potentially much larger. A “nanostructure” may include one or more nanocables. A nanocable may be fabricated with dissimilar materials, either as a core rod or wire that is laterally enveloped by one or more layers of material(s), as a nanotube that is filled with one or more layers of material(s), as a single structure of one material, etc. Nanocables are also interchangeably referred to as nanotubes, nanorods, nanowires, filled nanotubes and bristles. The functional element of the nanocable in each case is the interface(s) between the two (or more) materials. In various alternative configurations and modes of growth, a succession of layers of different materials, alternating materials or different thicknesses of materials can be deposited to form nested cylinder nanocables.

The term “photovoltaically active p-n junction” denotes any p-n junction with an adequate p-layer and n-layer thickness to generate electricity.

A method according to one general embodiment includes adding a template to a substrate; depositing conductive material in the template thereby forming an array of conductive nanocables on the substrate; removing at least part of the template; and depositing at least one layer of photovoltaic material on exposed portions of the conductive nanocables.

A nanostructure according to one general embodiment includes an array of nanocables extending from a substrate, the array of nanocables having physical characteristics of having been formed using an at least partially removed template; an insulating layer extending along the substrate; and at least one layer of photovoltaic material overlaying portions of the nanocables.

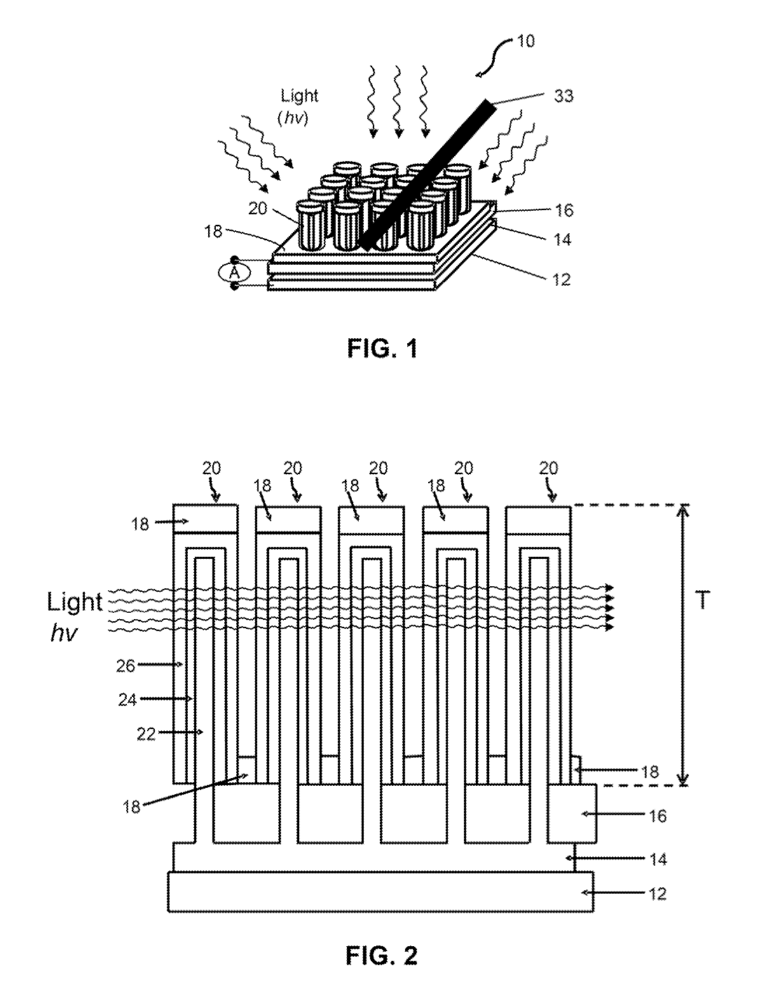

FIG. 1 is a perspective view of an exemplary solar brush 10 that may be used to implement solar cells with improved efficiency. As shown, the solar brush 10 has a substrate 12, a first conductive layer 14, an insulator layer 16, a second conductive layer 18, and a plurality of bristles 20. Although the bristles 20 are shown to be cylindrically-shaped in the particular embodiment, they may be of any other shape including but not limited to cones, rectangles domes, or more complex geometries such as branched bristles, elongated ovals, elongated rectangles, elongated polygons, etc. Each of the bristles 20 has a nanocable extending through its center, and layers of semiconductor around the nano or micro cable. The nano or micro cable may be thin relative to the PV coating, in some approaches. In that case, the bristles may be slightly reflective but mostly transparent. There can also be diffraction that will help distribute light throughout the cell. Alternatively, the bristles can be very thick relative to the photovoltaic coating in some approaches; that is to say that the bristles may be at micro scale and the coating may be at the nano scale. In that case, diffraction and reflections still distribute light throughout the device. Bristles may protrude vertically from the substrate or may protrude at angles. Bristles protruding at angles may increase the amount of semiconductor materials exposed to the sun when the sun is directly overhead and may improve internal reflections.

Bristle angles can be created by heating a polymer membrane and creating an asymmetric drag to get a template with tilted apertures into which a material may be formed, e.g., by electroplating. Deformation of the template may be performed, in one embodiment, by having a heat source, a source of drag, and an optional cooling source. One example would be a doctor blade scraping the heated top of a polymer membrane while the substrate is cooled with a cooling block, cool air, cool water, etc. A heated air knife may be used to replace the doctor blade. This also may be done with two contact rolls where one roll is cooled and moving at slow speed and another roll is heated and moving at a slightly faster speed. Additionally, seeding processes/vapor processes may be used on tilted surfaces to grow nanowire arrays at angles. Various shapes may be obtained using asymmetric pore membranes, according to various approaches. One or more electrically conductive strips 33 may extend across the array or portion thereof to assist in carrying electricity away from the array, thereby improving the overall efficiency of the brush. The efficiency gains are more pronounced in larger arrays. Such strips 32 are preferably very thin to block minimal light, in one approach.

FIG. 2 is a side cross-section of the solar brush 10 with a metal nanocable, according to one embodiment. As shown, each of the bristles 20 has a nanocable 22 extending through its core. The nanocable 22 is typically a p-layer conductor, and extends through the insulating layer 16 to electrically connect with the first conductive layer 14. A p-type semiconductive layer 24 of a sufficient thickness surrounds the nanocable 22, and an n-type semiconductive layer 26 of sufficient thickness is coated on the p-type semiconductive layer 24 to create a photovoltaically active p-n junction in each of the bristles 20. An n-layer conductor is deposited on the tops of the bristles 20 and the insulating layer 16 to form the second conductive layer 18.

In some approaches, the first and/or second conductive layers 14, 18 (or other layer or set of layers) are each contiguous, thereby simplifying manufacture, maximizing conductivity, reducing the chance of construction defects, etc. In other approaches, the second conductive layer 18 (front contact layer), first conductive layer 14 (back contact layer), and/or other layer or set of layers is segmented for forming electrically isolated segments thereof. Thus, a defect such as a short in a small section of the cell can be isolated and prevented from affecting neighboring portions of the PV cell. Segmentation of any of the layers may be effected using any known technique, such as etching, ablation, mechanical scoring, etc. Sections may be individually tested with only good portions of the device bussed together.

Separate groups of nanocables, such as rows, can be bussed or combined with metal and dielectric deposition so that any number of rows can he isolated for plating. For example, the segmented areas of conductive layer 18 may be bussed prior to plating such that energy may be delivered to one part of the array and not others. By switching segments on and off, two or more different compositions (different materials, material sets having different concentrations or elemental ratios, etc.), layers having differing thicknesses, etc., may be plated on different portions of the array, resulting in groups of bristles or portions thereof having different characteristics and/or properties such as different compositions, diameters, heights, affinity to certain wavelengths of light, etc. The segmentation may bus not only individual rows, but with patterning techniques to those skilled in the art, one may bus every other bristle in a basket weave type design, or any other possible division of bristles down to individual bristles. There can be any number of materials electroplated in a basket weave design, and moreover bristles can be optimized to PV thicknesses or material types which are especially suited for parts of the spectrum, according to one embodiment.

In addition to modifying or treating the back contact from the conductive base, the bristles themselves can also be modified with materials that can serve as improved back contacts. Such materials include Sn, An, Cu, C, Sb, Au, Te polymers, metal oxides, Si, SiO₂, S, NiO, Ni₂O₅, NiS₂, Zn, Sb₂Te₃, Ni, NiTe₂, Si, SiO₂, Cu, Ag, Au, Mo, Al and Te/C or combinations thereof. One may perform electrochemical deposition (ECD) of the nano or micro cables with an alloy of Ni and Cu, according to one embodiment. The alloying may minimize the diffusion of Cu during the heat activation step. One may also ECD coat a thin layer of Te on top of the alloyed nano or micro cable as a diffusion barrier, according to one embodiment. Nickel can be etched with a 10% HCl solution so that oxide is removed but the nano or micro cable stays intact. With that clean layer, CuSO₄ solution may be applied and heat treated to cause Cu diffusion into the nano or micro rod prior to plating. Varying degrees of oxides such as SiO₂ can also be added to the microrod surface effect to modify the plated composition, according to one embodiment.

In a further approach, a thin metal oxide layer may be formed or allowed to remain over the metal contact, e.g., Ni layer, to create a diffusion barrier to the lower metal contact and the overlying PV materials. Generally, one would expect an oxide layer to detrimentally affect performance by creating too much electrical resistance for proper operation of the array. Surprisingly, and counter to conventional wisdom, such an oxide layer was formed in an experiment, and was found not to cause an overly-detrimental effect on electric performance of the array. In the experiment, a thin layer of NiₓO_{y} formed on the Ni lower contact due to exposure to oxygen. A CdTe layer was formed thereover. Surprisingly, the array functioned well. Moreover, it was found that the layer of NiₓO_{y} beneficially prevented diffusion of the Ni into the CdTe layer. Accordingly, in some embodiments, a layer of metal oxide may be formed between the lower contact and the PV materials. Such layer of metal oxide may be formed, e.g., by exposing the lower contact to an oxygen-containing environment (e.g., air, ozone rich atmosphere, etc.) preferably while being heated (e.g., to greater than about 100° C.); barrel ashing; to etc.

The closer the photon absorption event is to the p-n junction, the more likely the event will result in usable electricity. In the case of a nanobrush, a reflective back contacting layer is not required because the photon can continue along the linear path so that it can contact the material on the opposite side of the cell thereby achieving a double pass in each nanobristle. In FIG. 2, five cylindrical shell solar brush PV cells are shown. Thus, if the photon passes slightly off-center of the shell, it has the potential to come into contact with as many as the equivalent of 10 p-type layers (the layer where the solar event takes place) in this brush design. If the p-layer conductor is sufficiently small, most of the photons will pass through five thicker layers. In the actual case, the solar brush, with millions of bristles per cm², would effectively approach the efficiency of 100% of all usable photon energy. Without being constrained to any particular theory, some light that was previously considered unusable may excite electrons in a stream where reflected light has an additive effect so that the addition of two photons with less than the band gap of energy can create an additive effect that ejects the electrons from the PV material.

The substrate 12 may be a conductive material or a nonconductive material (coated with a conductive material), rigid or flexible. For example, the substrate 12 may be glass, doped silicon, diamond, metal, polymer, ceramics, or a variety of composite materials, etc. Thin metal foil or certain polymers may be used where flexibility is desired. Flexible materials may be processed, e.g., by vacuum, attaching them to a structure that has the correct dimensions or flatness during the process, according to one embodiment. Moreover, a template may be formed by depositing a template material such as a binary template material continuously on a substrate such as a metal foil being unwrapped from a roll, forming the template, and creating PV nanostructures as described herein using the template. Structural integrity of the nanocable will vary with material choices. In the case of brittle or easily deformable bristles, a flexible substrate material may be used if attached to a rigid or semi-rigid surface. The molded surface/flexible membrane may be of particular help when PV cells are desired for an aerodynamic surface such as an airplane part, the roof of a car, the surface of other vessels or portable devices. Adequately, thin metals may also be used and plated using a semi continuous reel to reel plating. In such systems, degrease, positive electropolish, negative electropolish, electrochemical depositions made semicontinuous via dancer rollers, rinse and drying operations are all feasible in this case. One advantage to such a system is a formation of a semiflexible matt analogous to a window blind.

Moreover, the continuous nature of such an array allows one to tailor a power output of the array to meet specific needs, rather than the current approach of providing a number of modular arrays to achieve at least the desired power output, and in most instances, more than needed. The approach may be achieved by any number of techniques such as cutting the array to a size that provides the desired power output, forming the array with characteristics tailored to the specific parameters desired, etc. For example, assume a customer needs a 20 kW output. If each 1-inch band of array provides 5 kW, a four inch section would be provided.

Each of the bristles 20 is a discrete nanoscale PV cell. Compared to conventional flat PV cells design where only a single “xy” planar surface is exposed to light, the solar brush 10 has a “xyz” or a three-dimensional surface. Thus, for a given volume, the solar brush 10 has a useful surface area that can be several times to thousands of times greater than the “xy” surface area of conventional PV cells. The area between solar bristles 20 may be sufficiently wide as to make the brush absorptive to the majority of photons. Additionally, the bristles may be thin enough to be partially transparent. This effective transparency and bristle spacing increases effective energy generation to happen from sunrise to sunset while flat PV cells work optimally when the sun is straight above the PV surface, according to one embodiment. Because the effective energy generation from the solar brush is expected to be many times higher than conventional PV cell technology, the weight per kilowatt generated would be many times lower. The thickness of the PV material is as important as the height and the spacing of the bristles. If the materials are sufficiently thin, electron- hole recombination ceases to damage cell efficiency, and up to a 15% gain above that of 29% theoretical efficiency of a single junction cell becomes possible. This would allow use in small applications such as charging electronic devices (cell phone, computer, PDA, etc.), use in medium scale applications such as light weight roof-top energy for industrial and agricultural power generation, and use in large applications such as a light weight energy source for transportation (automobile, aircraft, barges, etc.). The efficiency of the cell would also enable improved power generation in low light conditions. The wide range of spectrum adsorption may also generate power from infra-red light at night time.

In addition, the film thickness to grain size ratio may be tuned to capture a particular wavelength of light, as disclosed in U.S. Provisional Patent Application No. 61/310,227, filed Mar. 3, 2010, and which is herein incorporated by reference. Moreover, some approaches use a mixture of grain diameters to capture multiple spectrums of light. For example, larger grains may he used to capture longer wavelengths of light, while smaller grains are used to capture the higher energy/lower wavelength photons and produce higher-energy events.

Another advantage of using nano or micro cable structures is that the p-n junction associated with each nanocable has a smooth interface that results in a sharper junction. The smoothness is improved at nanoscale as the roughness (measured as rms-root mean square for instance) increases as the scale increases.

It should also be noted that though the axes of the bristles 20 are oriented normal (perpendicular) to the plane of the array in the drawings, the axes of the bristles may be tilted slightly (a few degrees from normal, e.g., 1, 2, 5, 10 or more degrees) or pronouncedly (e.g., 40-89 degrees). One reason why a tilted configuration may be desirable is to reduce unimpeded penetration of light into the array when the light is traveling in a direction normal to the array, according to one embodiment.

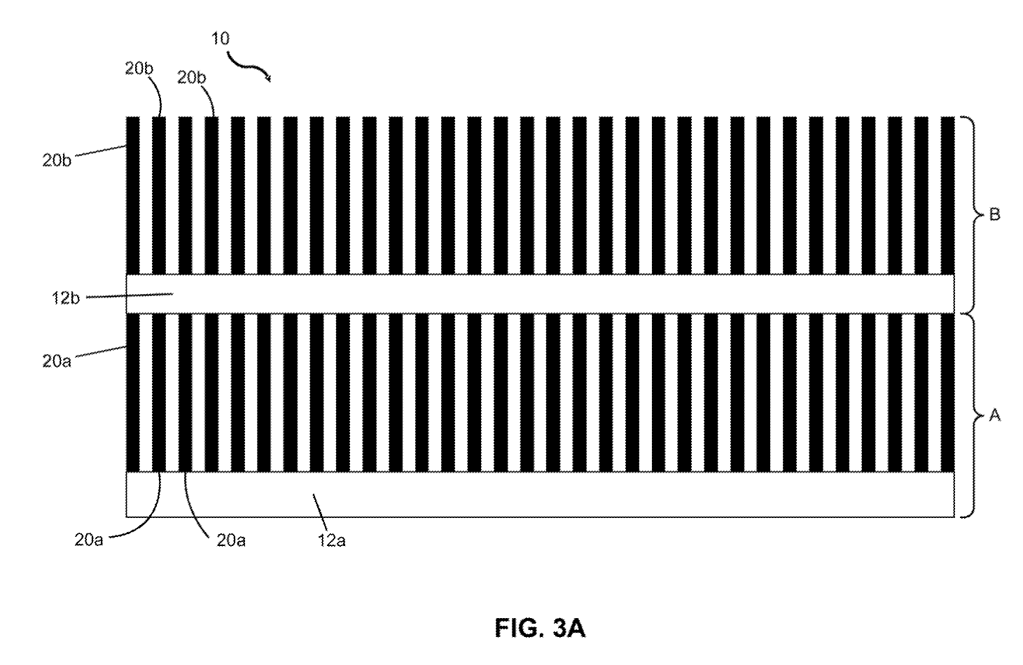

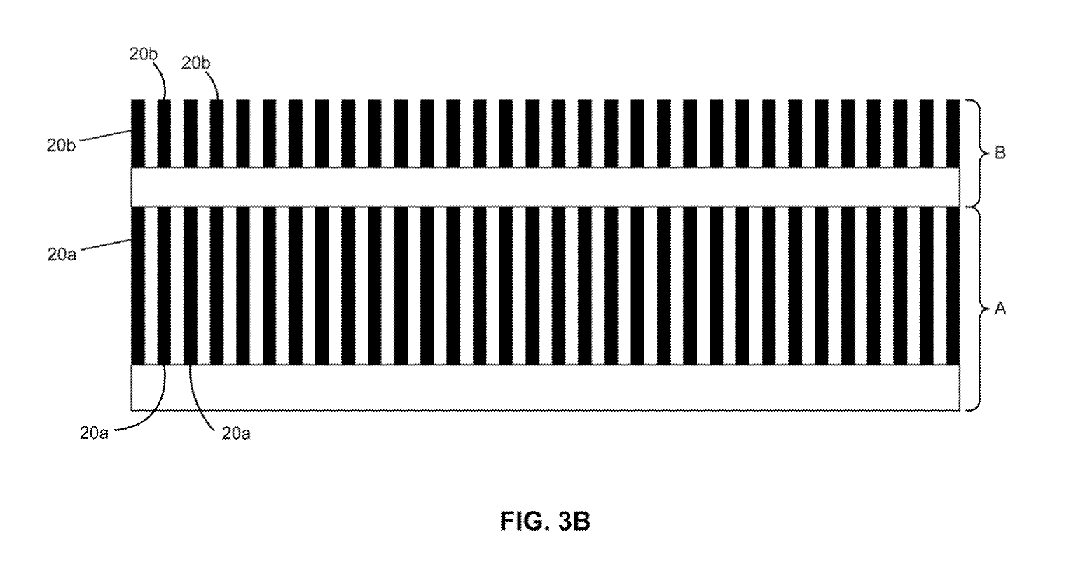

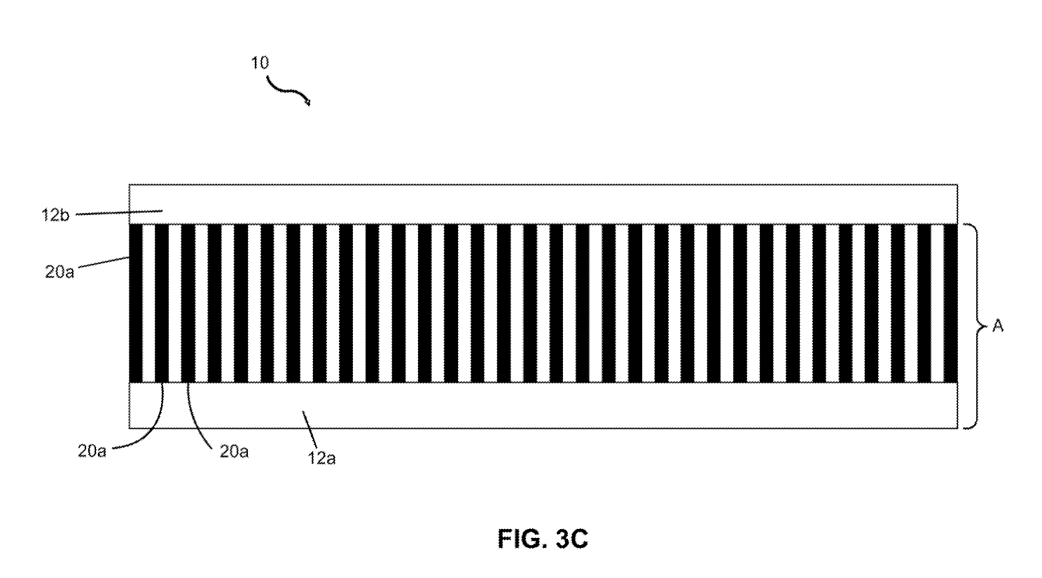

FIG. 3A is a perspective view of the solar brush 10 having a layered structure. The structure in FIG. 3A has a layer A and a layer B, with each layer having a substrate 12a, 12b, the first conductive layer (not shown), the insulator layer (not shown), the second conductive layer (not shown), and bristles 20a, 20b. In the layered structure, the substrates 12a, 12b, the first conductive layers, the insulator layers, and the second conductive layers of one or both layers may be at least semi-transparent so that light can travel between the layers A and/or B. When the solar brush 10 is layered, the bristles 20 do not have to be as densely arranged as in the single-layer structure to achieve the same efficiency, according to one embodiment. The layered structure can be made using cruder, and therefore less expensive, equipment than the single-layered structure with densely arranged bristles 20. Although the embodiment shown in FIG. 3A has two layers of approximately the same bristle height, this is not a limitation of a layered brush structure. Photovoltaic cells with layered brush structures may include as many layers as desired to generate the desired efficiency and power, according to various embodiments. For example, a photovoltaic cell with layered brush structures may include 3 or more layers of brush structures.

The layered brush structure may also be used to increase photovoltaic cell efficiency by using a high- and low-band gap material and semiconductor thicknesses tuned for spectral selection. A high band gap material may be used to coat the upper photovoltaic brush, and the low band gap material may be used to coat the lower photovoltaic brush. The upper material may convert higher-energy light to electricity and dissipate much heat. The lower material may convert lower-energy light. This increases both the efficiency and the life span of the lower brush A, according to one embodiment.

The layered structure does not need to be made of the same material or by the same process. For example, the upper brush may be produced using a conductive/transparent core of silicon and a silicon substrate made from photolithography and chemical vapor deposition and the lower brush made with organic dye technology. This way, the low-band-gap light can easily pass through the upper layer and reach, an organic nanocable base. The base may be made from an anodized aluminum template, carbon nanojacket, and wet polymer process. The layers may or may not have the same dimensions and/or composition. The design need not be limited to two types of photovoltaic cells. A multitude of cells can be included with a multitude of photovoltaic materials so long as each cell has adequate transparency for light to reach the cell below. Adequate light is determined by whether or not the brush structures at the lower level are capable of producing energy based on the amount of light that is received in operation.

FIG. 3B is a side view of another layered structure wherein the average brush heights are different in the two layers. The embodiment of FIG. 3B illustrates that there can be structural differences between the two layers.

FIG. 3C illustrates that a transparent thin film planar device can also be employed as a filter over a brush layer if desired. In this embodiment, the brush structures may be protected from damage by the planar device, may be more easily cleaned, etc.

Thin, minimal reflectance metals such as gold may be layered along with the n- and p-layers to conduct the current so further gains in efficiency might be achieved. Other metals may also be used, as would be known to one of skill in the art.

One benefit over current technology is, as previously mentioned, that the maximum efficiency for a given material may be achieved, according to various embodiments. Another potential benefit may be achieved by layering material with different band gaps (energies required to excite electrons). The idea is to have a high band gap material such as GaAs (max efficiency ˜20%, band gap ˜1.4 eV) or CdTe (max efficiency ˜30%; band gap ˜1.6 eV) at the tip of the bristle and a reduced band gap material further down the bristle such as CIS or CIGS type PV material further down (max efficiency of ˜24%; band gap ˜0.8 eV). Photons with low energy will not react with high band gap material but will be available to react with low band gap material further down the bristle at further penetration depths. This may he achieved by CVD of CIS material on a nanocable, followed by etching to the top metal core of the nanocable, followed by catalytic growth on top of the nanocable, and the cable would be finished up by electroplating of CdTe/CdS, according to one embodiment. The solar brush PV cell design may also be a multijunction cell and is a superior architecture for such.

A flexible nanopore substrate can be used as the substrate 12 for deposition of metal. The substrate 12 may be a membrane applied to or constructed on a thin conductive sheet, and may he made into any desired shape. After metal deposition in the membrane pores occurs, the bristles 20 are formed. While other PV tapes and films have XY flexibility and strength, they are limited and no other technology allows for XYZ design of a rigid or flexible long lasting solar cell. The varied geometry of the solar brush allows the PV cells to he optimized for solar exposure from a fixed location, optimal aesthetic appeal, and minimal aerodynamic drag for transportation applications, according to one embodiment. Specific geometries combined with reflective substrates can effectively produce a combined PV film and solar concentrator.

There are many combinations of materials that may be used for the solar brush 10. One configuration is to use a Si thin film. Other configurations include, but are not limited to, CdTe/CdS (CdTe/CdS/SnO₂/Indium Tin Oxide(ITO)/glass), GaAs/GaInP, CuInGaSe₂, Cu(InₓGa₁₋ₓ)(S,Se)₂, CuIn₁₋ₓGaₓSe_{1-y}S_{y}, CGSe/CdS, CuInₓGa₁₋ₓTe₂/n-InSe, CdS/CIGS interface, ZnS/CIGS, Cu₂S—CdS, CuInS₂ or a mix of CuₓS, CuInS₂ and CuIn₅S₈, Cu(In,Ga)Se₂/CdS, CIS/In₂Se₃, InN, CIS/In₂Se₃, ZnSₓSe₁₋ₓ. GaInP/GaAs, GaInP/GaAs/Ge, GaAs/CIS, a-Si/CIGS (a-Si is amorphous Si/hydrogen alloy), FeS₂, Cu₂O, ITO/a-CNx (Al Schottky thin-film carbon nitride solar cells), and MoS₂ based solar cells or more general: MX2 (M=Mo, W; X═S, Se) thin films with Ni and Cu additives layers may be used as well. An Al₂O₃ layer may be used as a diffusion barrier with the CuInGaSe₂ type PV cells, according to one embodiment. The manufacturing step may include heat annealing at high temperatures to allow for the consolidation of polycrystalline deposits to form a single crystal material or improve the structural integrity and regularity or geometry of the materials. Alternatively, single crystalline growth of layers may be favored by slow growth of the layers at moderate temperatures. Single crystalline deposits are important for optimum electron transport and photon absorption.

Deposition of the various materials may include chemical vapor deposition, solution phase deposition, electrochemical deposition, electrochemically induced sol-gel deposition, electrochemical atomic layer epitaxy, electroless deposition; e-beam evaporation, sol-gel with electrophoresis or centrifugation, electron beam lithography, scanned probe lithography, pressure injections, polymerization and electro-polymerization, pyrolytic decomposition, etc. Nanocables may also be grown from catalyst sites from chemical vapor deposition, wet or dry etched from a substrate, etc.

When designing a PV cell, one of the considerations is the photon flux. The number of photons that make it through the atmosphere at a given point remains relatively constant regardless of modifications in the PV cell that receives them. When determining the appropriate geometry for a PV cell, it is convenient to start by calculating the area of the gaps and the area of the bristle-tops.

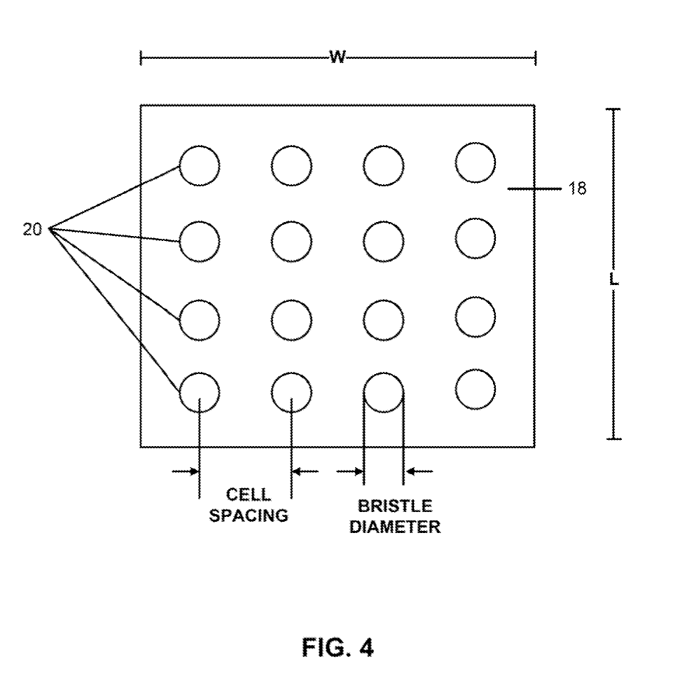

FIG. 4 is a top view of the solar brush 10 showing the tops-of the bristles 20. Although the bristles 20 are shown to be arranged regularly, this arrangement can be changed to suit the application, according to various embodiments. The tops of the bristles 20 have a combined area of Aₜₒₚ which is calculated as π(D/2)²ρ wherein D is the diameter of the bristle and ρ is the cable density (number of cables/unit area). The total area (Aₜₒₜₐₗ) of the PV cell is W×L. The area of the gaps between the bristles can then be calculated using the following formula:

Aₜₒₜₐₗ=Aₜₒₚ+A_{gap}

During the same calculation, it is useful to determine if the spacing for a given cable density is viable for given geometries. Presented by way of example only, and not meant to be limiting in any way, when the diameter of the nanocable 22 (D_{nanoable}) is 50 nm, the minimum PV bristle diameter D is about 220 nm. When D_{nanocable}=150 nm, the minimum PV bristle optical thickness is about 320 nm. The physical diameter of the bristles 20 will be 100-500 nm larger than the diameter of the nanocable 22, but these numbers should be used for the optical diameter calculations because the outer shell is transparent. The optical diameter is used for calculating the solar efficiency, and the physical diameter is used for determining process limits.

One preferred density (ρ) range for nanocables is:

ρ=10⁶-10⁹ pores/cm²=10¹⁰-10¹³ pores/m²

when using track etched membranes. When using metal oxide templates the density range shifts to:

ρ=10¹²-10¹⁵ pores/m²

For the low density case, there is 1 cable per 10⁻¹⁰ m², or 1 cable in the center of a 10⁻⁵×10⁻⁵ m square, so the separation between the center of cables is 10⁻⁵ m or 10000 nm. From that number, the diameter of the bristle from its center axis (which extends through the length of the nanocable 22) to the n-layer is subtracted. The spacing may not be smaller than the cable and is preferably larger, so cases involving unrealistic physical spacing were eliminated from calculations in Table 1. Optical spacing, S, is given by the following formula:

S=cable separation (center pt. to center pt.)−diameter a bristle (semitransparent material)

After optical spacing is determined, the areas of the top of the PV bristles (Aₜₒₚ) as well as areas between the bristles (A_{gap}) may be determined, according to one embodiment. Table 1 shows that majority of the planar surface area lies within the gaps of the PV cell, not the bristle tops. However, there are design points that have significant levels of top surface area.

TABLE 1
Planar area calculations for the PV brush.

| Aₜₒₚ | A_{gap} | ρ | D | S |
|---|---|---|---|---|
| (m²) | (m²) | (#/cm²) | (nm) | (nm) |
| 3.00 × 10⁻⁴ | 0.9996 | 10⁶ | 220 | 9780 |
| 8.04 × 10⁻⁴ | 0.9989 | 10⁶ | 370 | 9680 |
| 3.80 × 10⁻² | 0.9620 | 10⁸ | 220 | 780 |
| 8.04 × 10⁻² | 0.9892 | 10⁸ | 370 | 680 |
| 1.90 × 10⁻¹ | 0.8100 | 5 × 10⁸ | 220 | 227 |

Planar area and mass per area are useful to determine back reflection. For planar cells, reflection bounces much of the light out of the PV cell before it has a chance to be absorbed and generate electricity. However, back reflection can benefit the planar cell by bouncing the light off of the back of the cell to give the cell two opportunities to absorb photons from the same stream of light. However, while the back reflection increases the number of absorptive events in the planar cell, it also increases the amount of heat generated per unit volume. In the case of the solar brush 10, only a fraction of the photons that hit the bristle tops can reflect away from the PV cell.

In many cases with the solar brush 10, over 96% of the light falls into A_{gap}. Several things happen to the light that falls into the gap: (a) the light is absorbed, (b) the light continues straight through the bristle into the next nearest bristle (as shown in FIG. 2), and/or (c) the light is reflected down into the solar brush at an angle of reflection equal to the angle of incidence. In each case, the light from the gap continues into the bristle. The majority of the light is either absorbed or continues straight through the brush. Back reflection is a function of material thickness as well as material type. Because the solar brush is made up of millions of thin bristles, they become nearly “transparent.” Thus, in every case except Θ=90° (where Θ is defined as the angle of the sun relative to the plane of the PV cell substrate), back reflection is minimal. If it is assumed that 96% or greater light falls within the gap and each bristle has 90% transparency, then there is a maximum of 0.04% back reflection, according to one embodiment.

The depth and areas of penetrated light may also be calculated. This is a measure of how uniformly the light can be dispersed throughout the PV brush. The penetration of light is governed by the following formula:

Tₚₑₙ=penetration thickness=S tan Θ

The thickness or bristle height is related to the maximum penetration. The average penetration for a light stream in many cases would be about Θ/2. However, as Θ approaches 90°, the bottom of the cell may be theoretically flooded with light. However, in reality, this flooding effect is minimal or nonexistent because the light is affected by irregularities in the bristle geometry and can be eliminated by tilting the bristles slightly, according to one embodiment.

The penetration % is a useful design criterion. For example, for transparent cables, if there is 10% penetration, the light will have as few as 10 passes through PV cables, and the average photon would have up to 20 passes through the p-n junction since the photon may pass through the p-n junction twice per bristle. It is probably best to set design criteria to target less than 20% for most of the day to ensure adequate absorption opportunities for the light stream. When Θ goes to 90°, tan Θ goes to ∞, temporarily making the penetration level 100%. Optimization, however, will generally be a function of field testing results.

The total PV absorption area is much greater for the sides of the bristles 20 than for the tops. A_{cell} is the surface area available by PV brush which is given by:

A_{cell}=T(π)(Dρ/2)

where T is the height of the cable, D is the optical diameter of the PV bristle, and ρ is the number of bristles per unit area. The quantity is divided by 2 because it is assumed that most light absorption will come from the sun which is shining on half of the cell at one time. There will be significant absorption events from scattered light as well, but the majority of photons typically come directly from the sun.

The penetration area is proportional to the penetration depth, as shown by the following formula:

Aₚₑₙ=area initially penetrated by light=Tₚₑₙ(π)(Dρ)

Where A_{gap}>>Aₜₒₚ the dilution of light is represented by the following formula:

Aₚₑₙ=Tₚₑₙ/T*Aₜₒₜₐₗ

From Aₚₑₙ and A_{gap} (Table 1), a calculation that shows the amount of light dilution that occurs in the cell can be made. The light dilution is useful for opportunities for solar absorption events and uniform heating. More dilute light leads to lower maximum temperatures or fewer hot spots in the cell, resulting in improved overall efficiency. Wherever there are hot spots, there is rapidly degrading conversion efficiency. Wherever there is concentrated light that tends to create hot spots, the ratio of opportunities for an absorption event to the number of photons decreases.

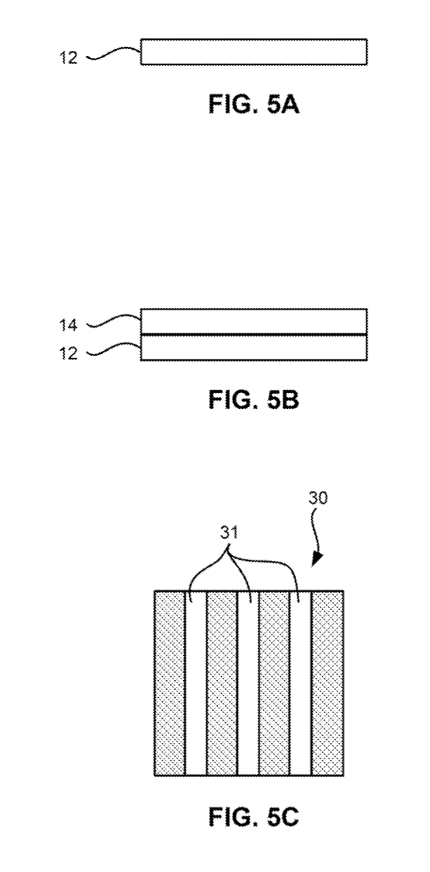

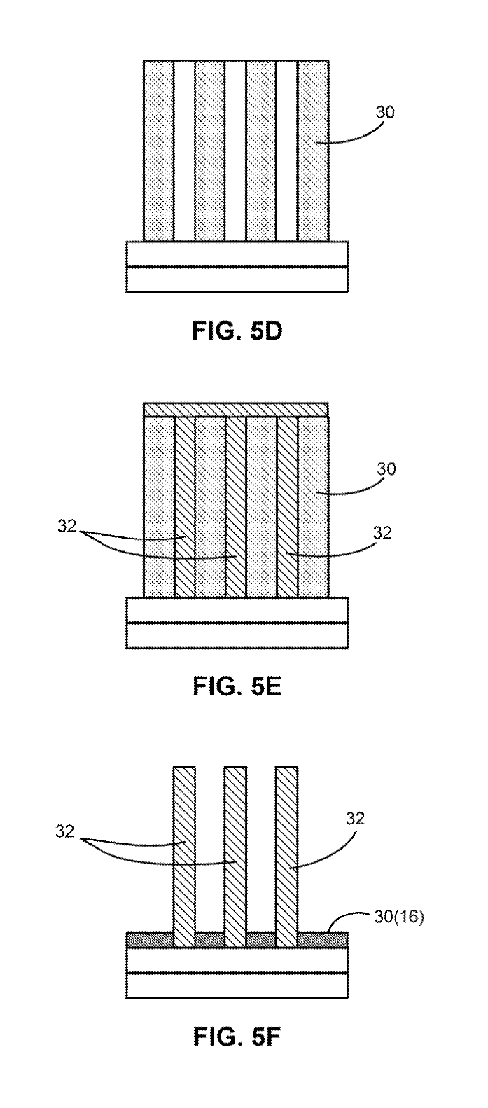

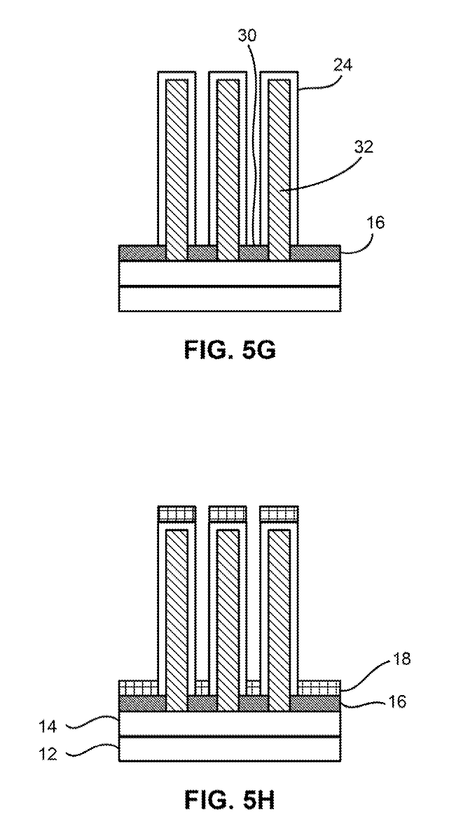

FIGS. 5A-5H illustrate an exemplary method for preparing the solar brush 10 including a metal substrate and bristles of CdTe and CdS, according to one embodiment. As shown in FIG. 5A, a substrate may be prepared by sonicating with ultra pure water (e.g., 18 MΩ) and ethanol in an alternating manner. For example, a metal substrate may be sonicated with ultra pure water for 10 minutes, then with pure ethanol for 10 minutes, and this water-ethanol cleaning cycle may be repeated two more times, according to one embodiment. If desired, the cycle may he performed more or less than three times and/or an initial detergent-water, acid-water cleaning, or NaOH/NaCN/detergent electropolish process may be added. The type and amount of cleaning that is appropriate is a function of how clean the substrate 12 is to begin with, and the type of material the substrate 12 is made of.

The substrate 12 may be a conductive material (e.g., metal) or a nonconductive material (e.g., glass, polymer, etc.) that is coated with a conductive layer.

FIG. 5B illustrates the substrate 12 coated with the first conductive layer 14 that serves as the p-layer conductor in the PV cell. The first conductive layer 14 may be any well-known conductive material deemed suitable by a person skilled in the art, including but not limited to gold, copper, nickel, molybdenum, iron, aluminum, doped silicon, silver, etc. In one embodiment, a 500-nm layer of gold is evaporated on a glass substrate at 0.2 Å/s using an electron beam evaporator at a pressure under 5×10⁻⁶ mbar at room temperature. In other embodiments, electroless plating is used with copper salts or Na₃AuSO₃ dissolved in 50 mM H₂SO₄. After metallization of the substrate 12, the surface of the first conductive layer 14 is rinsed with ultra-pure water (e.g., for 1 minute), rinsed with ethanol, and dried with nitrogen, according to one embodiment.

FIG. 5C illustrates a template 30 that may be used to form the bristles 20, according to one embodiment. The template 30 may be a membrane or porous structure that can be constructed on a conductive base. Selection of the membrane 30 depends on the particulars of the PV cell that is being fabricated. Different p/n combinations have different thickness requirements and therefore different cable size requirements. In one approach, a membrane may be formed by first depositing a thin conductive material such as 200 nm Ni, followed by depositing an insulating layer such as 200 nm SiO₂ or Si₃N₄, spin coating approximately 3-20 μm of polyimide or photoresist polymer, optionally layering on a thin metallic or oxide hard mask, and another photoresist, according to one embodiment. In another approach, the template is formed at least in part from a photoresist that is patterned without a hard mask. Alternatively, the template may be made with an embossible material. In yet another approach, a template may be made by filling in a structured substrate with polymer and removing the polymer from the substrate such that holes of any number of geometries are produced. Although embossing may be used to go all the way through a material such as the case where SiO₂ is applied though CVD to a thin membrane, and the membrane is run through an embossing tool that creates holes through both layers, embossing can optionally be followed with an etch step that cleans out the oxide and improves the geometry of polymer holes. A nano or micro embossing tool that is usually, but not necessarily heated, creates embossing, according to one embodiment. First, the hard mask is patterned with holes that are typically 35 nm to many microns using photolithography, then deep etching is performed. The etching may be pulsed to in order to allow the waste stream to leave the via. The upper photoresist is preferably removed while the via is being formed. After the via is formed to the insulating layer, a polymer coating possibly fluorinated polymer can be added to the via prior to etching through the insulator. After the insulator via is etched, oxides on the conductor may be removed. For metals such as nickel, an HCl solution or 100:1 HF or reactive H+ may be used to remove the oxide, according to some embodiments. Environmental care or immersion in water may be done prior to electrochemical deposition. In all cases, surfaces with minimal oxide levels are useful in the process, since they provide good adhesion of electrochemically deposited nano or micro cable, according to one embodiment. Before electrochemical deposition, the gas bubbles are expelled from the pores by submerging the membrane 30 in water and sonicating for 5 minutes. The back contact may be etched, scribed, or otherwise mechanically scored, laser ablated and the like, to form discrete, segmented areas on the cell to avoid defects in one area if the cell to affect others. Separate rows may be bussed or combined with metal and dielectric deposition so that any number of rows may be isolated for plating, as would be known to one of skill in the art. One may produce one row CdTe and one row CIS type product. Furthermore, a basket weaving type of deposition may create an array where every other bristle has an alternating thickness and composition, according to one embodiment. Next, one or more transparent conductive oxides is applied, such as F:SnO. Etching can be performed so that the base of the bristle widens and provides sufficient curvature to allow for deposition techniques such as sputtering and CVD of high aspect ratios, according to one embodiment. Liquid transparent conductive oxides (TCO) also exist such that the TCO application is sufficiently hot as to activate the photovoltaic cell. Alternatively, a membrane may be continuously produced using cylinder with metallic posts that has polymer sprayed on it such as those membranes created by 10X Technologies, according to one embodiment. Another alternative would be to emboss a thick polypropylene film using conventional embossing techniques like those employed by paper and diaper manufacturers. If the membrane is sufficiently thick, it is possible to heat the top while cooling the substrate, then applying a force through a squeegee, doctor blade, air knife, and the like that causes the pores in the membrane to tilt, according to one embodiment.

Alternatively, a template or membrane can be continuously produced using a cylinder with metallic posts that has a polymer sprayed on it such as those membranes created by 10X Technologies. Another alternative would be to emboss a polymeric (e.g., thick polypropylene) film in a continuous or batch embossing process using conventional embossing techniques like those employed by paper and diaper manufacturers.

Selection of the membrane 30 depends on the particulars of the PV cell that is being fabricated. Different p/n combinations have different thickness requirements and therefore different cable size requirements, according to one embodiment. Before electrochemical deposition, the membrane 30 is cleaned and air bubbles expelled from the pores by submerging the membrane 30 in methanol and sonicating for 5 minutes.

FIG. 5D illustrates the membrane 30 connected to the substrate 12 that has been coated with the first conductive layer 14. There are a number of ways to connect the membrane 30 to the conductive substrate 12 or the metalized nonconductive substrate 12. For example, a TiO₂ solution may be used as a conductive glue to fix the membrane to the surfaces, according to one embodiment. Alternatively, the membrane may be fixed using a Radionics Silver Conductive Paint®. Some substrates require no adhesion. The membrane is simply placed on top of the substrate provided there is good surface contact. Alternatively, the membrane may be attached to the surface with a clamp, using ultrasonic welding, by fitting the surface and the membrane into a jig, etc.

Final etching through the insulator film may still be required as would oxide removal, according to some embodiments.

Following the template formation, nano or micro cable may be formed using any number of solutions. Nickel is widely used in MEMS devices and is compatible as a back contact for many PV devices, and is therefore a good choice. Other metals are also available to use, as would be known to one of skill in the art. There is a wide range of commercial nickel baths that are appropriate for the template. Constant potential deposition is generally preferred for precision bristles, but processes can easily be built for constant current deposition as well.

In one approach, after the micro or nanocable is formed, the polymer is ashed away using a barrel asher or similar plasma and wet etched to remove residue, according to one embodiment. Prior to plating, the oxide removal process is repeated on the nano or micro bristles to create a high quality back contact, according to one embodiment. Acidic CdTe plating may be performed at a pH of about 1.75, saturated Te from TeO₂ and CdSO₄ at about 100 times the concentration of the Te. Care should be taken to keep the bath clean and keep any contaminants from the bath. Constant potential deposition of CdTe may be performed anywhere between about 60° C. and 90° C. Potentiostats can be easily adjusted between 0.3V and 0.8V to deliver slightly P type CdTe, according to one embodiment.

Following CdTe deposition, electrochemical or immersion CdS plating may be performed using well known materials, such as thiourea, thiosulfate baths, etc., at about 65C to 80C. Finally, CdCl₂ at about 1% in water or methanol is heated in contact or proximity of the surface at about 100° C. to 500° C. from about 30 sec to 45 minutes, depending on the thickness of the CdTe, according to various embodiments. Lastly an indium tin oxide or fluorinated tin oxide coating is applied to the cell and the fabrication of the cell is complete, according to one embodiment.

FIG. 5E illustrates the deposition of metal 32 into the membrane 30 and on the substrate 12. In an illustrative plating process, and not meant to be limiting on the invention in any way, a Sn sensitizer is applied to the membrane 30 through about a 5 to 45-minute immersion in 0.26M SnCl₂ and 0.07 M trifluoroacetic acid dissolved in a solvent having a molar ratio of 1:1 methanol to water. The membrane is rinsed with methanol. Sn²⁺ adheres to the pore walls and outer surface of the membrane. Next, the membrane is immersed in an aqueous solution of 0.029 M ammoniacal AgNO₃ for about 5 minutes. This causes a redox reaction where Sn²⁺ is oxidized to Sn⁴⁺ and Ag⁺ is reduced to elemental Ag. Some silver oxide is also generated, according to one embodiment.

The pore walls and the membrane 30 become coated with discrete nanoscopic Ag particles. The membrane is rinsed with ethanol and immersed in water. Then the membrane is immersed in a 7.9 mM Na₃Au(SO₃)₂/0.127M Na₂SO₃/0.625 M formaldehyde solution that has a temperature of about 0° C. Gold plating is continued for 10 to 24 hours (time is dependant on pore size), at which time the nanocables are fully formed in the membrane, according to one embodiment.

An alternative way to deposit materials inside membranes entails using electrophoresis or centrifugation sol-gel methods, electrochemical atomic layer epitaxy, chemical vapor deposition, sputtering, E-beam evaporation, thermal evaporation, electron beam lithography, and scanned probe lithography. Alternatively, well known additives can be dissolved in the solution to impart nanocable strength or better electrical connections to the n-layer conductor. Preferably, metal covers all exposed areas of the membrane, substrate, and fills the pores, according to one embodiment. After the gold deposition, the membrane is soak with water and rinsed 4 times over a 3-hour period and immersed in 25% nitric acid for 12 hours to remove residual Sn or Ag. Finally, the membrane is rinsed with water and air dried. Evaporative metal deposition can also take place in the same manner as in FIG. 5B. One advantage of electroless or electro-deposition is that it does not require a clean room or high temperatures to deposit the metal on the substrate.

Alternatively, the membrane may be placed into the electroless plating solution by itself. The top, bottom, sides and pores become metalized. The membrane 30 may be glued or otherwise coupled, as mentioned above, to the metalized substrate 12.

If desired, atomic layer epitaxy may be used to build a protective cover over the membrane 30. Atomic layer epitaxy may be used as an alternative to electrochemical epitaxy.

FIG. 5F illustrates the removal of the membrane 30, according to one embodiment, leaving the conductive cables (nanowires) 32 attached to the substrate 12. Membrane removal is may be performed by solvent extraction. Partial membrane removal is often desirable. Layered membranes make it easier to achieve uniform partial dissolution. Generally, ashing, RIE or solvent washes are used to remove the polymer or photoresist membrane. Regardless, the array of nanocables will have physical characteristics of having been formed using an at least partially removed template, such as sidewall shapes and/or textures characteristic of the interface formed between the nanocables and the previously-present template; an interface with a remaining portion of the template; etc.

As shown in FIG. 5F, the membrane 30 may be binary in nature so that a solvent or removal technique has a high selectivity towards the polymer or photoresist, but leaves the insulating layer 16 portion thereof intact. Alternatively, the membrane may be completely dissolved and an insulating layer deposited using any suitable method such as spin coating, CVD, etc.

The insulating layer 16 may keep the current from the n-layer and p-layer from short circuiting. The insulator can also limit deposition of PV material to the nanocables. Because insulation eliminates the effects of defects of one cable from affecting its neighbors, processes like electroplating become feasible.

Electroplating is a desirable process because of low equipment costs and relatively good material conservation relative to other processes such as sputtering and CVD which deposit material throughout the chamber in addition to in the desired area. The thickness may easily be determined by using various exposure times to dichloromethane and verifying the membrane thickness with scanning electron Microscopy.

If all of the membrane 30 is removed, excessive material is consumed. This process may be used if a thinner insulating material or a material other than the material the membrane 30 is made of is desired to form the insulating layer 16. In this case, the desired material may be spin-coated on the substrate 12 with polymethylmethacrolate (PMMA) to a thickness of about 1 μm, according to one embodiment. The PMMA may function as a membrane glue and/or an insulator. Any insulating material that can be applied to the PV cell be it polymers, silicon dioxide, or any insulator that can have adequate dimensional control during application. The PC membrane may be placed on top of the PMMA and baked at around 100° C. for about an hour.

In some embodiments, the insulating layer is eliminated altogether. As long as the p and n layers are adequately produced, direct contact with the conducting layers is possible.

In other embodiments, holes are made in the insulating layer after attachment of the membrane. For example, reactive ion etching (RIE) with oxygen and/or wet etching may be used to drill through the insulating layer 16 to allow the nanocables 32 to connect with the first conductive layer 14.

In other embodiments, membrane can actually be used as a masking layer to etch pores in the underlayer, which is the insulating layer 16 in this case.

FIG. 5G illustrates the deposition of a p-type semiconductive layer 34. Where the p-type semiconductor is CdTe, for example, the electrochemical deposition is done using 50 mM H₂SO₄+1 mM CdSO₄+0.1 mM TeO₂ solutions by cycling to 95° C. and cooling to 72° C. The reference electrode may be Ag/AgCl/3 M NaCl and the counter electrode may be a gold wire. Ultra-pure (e.g., 18 MΩ) water rinses are performed between deposition steps with nitrogen drying. A thin layer of Te may be deposited to prevent Cd diffusion into the nanocable. When CdTe layer is deposited in an electrochemical cell from a solution of 0.5M CdSO₄ and 2.4×10⁻⁴ M TeO₂ in water at a pH of 1.6 at 90° C., the optimum deposition potential for a stoichiometric film is varies with the surface plated, but is typically between about 300 mV and 900 mV. CdTe may also be deposited in ammonia solutions, according to one embodiment. Te deposition on the bristle surface can eliminate Cd diffusion into the core of the PV device. The CdTe layer also can be deposited by ECALE (electrochemical atomic layer epitaxy), ALD (atomic layer deposition in chemical vapor deposition system), sol-gel techniques, etc. When non-electroplating processes such as CVD-related methods are used, etching can be used to remove the p-type layer 24 at the base of the structure to expose the insulation layer and create isolation between the nanostructures, according to one embodiment.

FIG. 5G also illustrates the deposition of an n-type semiconductive layer 36, according to one embodiment. Where the n-type semiconductor is CdS, CdS deposition is performed using any suitable technique. For example, CdS deposition may be performed in a chemical bath comprising one or more of a sulfur-containing material; a Cd-containing material such as cadmium acetate, cadmium sulfate, cadmium iodine, etc.; and additive(s) such as a pH controlling material such as ammonia, triethylamine, etc; etc. The CdS layer may be deposited to a deposition thickness of between about 30 nm and about 200 nm. An illustrative deposition time is between about 15 and about 90 or more minutes. In another approach, several temporally-shorter depositions may be performed, optionally with a thermal anneal and/or densification performed between chemical bath deposition steps. The resulting layer has a physical structure characteristic of formation thereof by multiple chemical bath depositions with at least one of a thermal anneal and a densification performed between the chemical bath depositions. Such characteristics are observable upon dissection and/or analysis of a bristle so formed.

In another illustrative approach, CdS deposition is performed in 1.5 mM SC(NH₂)₂, 1.5 mM Cd SO₄, and 2 mM NH₄OH heated to a temperature of about 40° C. to about 70° C. Under these conditions, a 4.5 minute exposure would lead to a CdS layer of about 30 nm.

The CdS layer also can be deposited by ECALE (electrochemical atomic layer epitaxy), ALD (atomic layer deposition in chemical vapor deposition system), sol-gel processing, low pressure CVD, etc. Again, when non-electroplating processes such as CVD-related methods are used, etching can be used to remove the p-type layer 24 at the base of the structure to expose the insulation layer and create isolation between the nanostructures.

FIG. 5H illustrates the deposition of the second conductive layer 18 that completes the PV circuit. The second conductive layer 18 may be added using atomic layer epitaxy. This deposition connects the second conductive layer to the base of the n-conductors without contacting the nanocable. Alternatively, a thin layer of electroless metal can be coated as in the process illustrated in FIG. 5B as long as the metal remains thin enough to maintain adequate transparency. Yet another alternative is to apply a transparent conductive polymer such as poly(3-hexylthiophene) (P3HT), poly[2-methoxy,5-(2-ethyl-hexyloxy)-p-phenylene-vinylene] (MEH-PPV), poly (phenylene vinylene) (PPV), and polyaniline to the outside of the nanocables to complete the circuit. The polymer may also provide additional structural support. Since the PV circuit is built on the nanoscale, penetration of the polymer may be challenging. For this reason, thinner solutions may be preferred, according to one embodiment. However, exposing the upper surface of the PV cell would provide adequate conduction. Preferred polymers are light and oxygen stable. Many different conductive polymers are useful to make the electrical contacts and are described in T. A. Skatherin, Handbook of Conductive Polymers I, which is incorporated by reference in its entirety.

Under some circumstances it may be economical and desirable to build a conductive grid (e.g., parallel conductors, hub and spoke configuration, crossed conductors, etc.) above the insulating layer and between the cables to augment the current carrying capacity of the top conductive layer (e.g., TCO). The grid may be formed of any conductive material, a metal or metallic alloy being preferred. The grid preferably does not contact the PV layers of the bristles, and may be formed under or above the upper conductive layer. The grid may be coupled to a collection circuit, coupled to a bus, etc. Such grid may be used in some embodiments to overcome challenges with optimizing TCO transparency and conductivity and/or to enable use of a conductive polymer that might otherwise be adequate. Preferably, such grid is located where it does not block light. Moreover, if the grid is reflective, it may provide a nominal amount of reflection that may be beneficial. In one approach, the grid may be deposited during building the insulating layer(s) before patterning the bristles. In another approach, the grid may be formed after the n-layer is applied and the bristles are segmented. Other formation techniques may also be used.

Additionally, gel electrolytes may be used to make the electrical contact for the n-layer as shown in U.S. Patent Application No. 2004/0025933, which is herein incorporated by reference. The electrolyte solution may be a combination of poly(4-vinylpyrinidine), poly(2-vinylpyrinidine), polyethylned oxide, polyurethanes, polyamides and a lithium salt. The salt may be lithium iodide, lithium bromide, lithium perchlorate, lithium thiocyanate, lithium trifluormethyl sulfonate, and lithium hexafluorophosphate to name a few.

Although FIGS. 5A through 5H illustrate an exemplary method of fabricating the solar brush 10, there are many suitable variations of the process, according to many embodiments. For example, an organic photovoltaic material may be used. For example, PV cells may be made based on Dr. Michael Grätzel and co-worker's technology developed at the Swiss Federal Institute of Technology. The metallic core of the nanobristle may be made of metal oxides based on Ti, Zr, Sn, W, NB, Ta, and Th. The cables can then be coated with an organic dye such as xanthines, cyanines, mercocyanines, and phthalocianines, and pyrols. Many of these compounds have been tested by Konarka Corporation and have been developed for low temperature sintering as illustrated in U.S. Patent Application No. 2004/00259934, which is herein incorporated by reference. Fortunately, the nanocable eliminates the sintering concerns and allows the organic compound to be easily applied and efficiently used on the surface of the nanobrush.

Also, any membrane with micropores may be applied to the substrate 12 to produce the PV brush, according to some embodiments. Also, any metal deposition may work with nanopores be it chemical vapor deposition, plasma vapor deposition, metal organic vapor deposition, electrochemical deposition (electrochemical epitaxy, under-potential deposition), liquid phase epitaxy, molecular beam epitaxy, hot wall epitaxy, sputtering, E-beam and thermal evaporation, electroless deposition, chemical bath deposition, sol gel and solution methods, vapor-liquid solid methods, sonochemistry methods, microwave methods, etc.

In any of the embodiments described herein a transparent or substantially transparent dielectric overcoat may be applied to the solar brush. The deposition thickness may be less than, equal to, or greater than the height of the nanocables. Any known material may be used. Preferably, the dielectric overcoat is applied in liquid form, according to one embodiment, thereby reducing the risk of breaking any of the nanocables during application thereof. Particularly preferred materials include resins and polymeric materials, such as liquid ethyl vinyl acetate (EVA), which is typically deposited and cured. Moreover, any known deposition technique may be used, including dipping, spraying, spin coating, etc. Preferably, the dielectric overcoat is applied after the front electrical contacts are made, thereby sealing the cell from the elements.

As noted elsewhere herein, the overcoat material may he heated prior to the deposition to a sufficient temperature to photovoltaically activate the nanostructures such that application of the overcoat activates the photovoltaic nanostructures, according to one embodiment.

In one approach, the PV cell can be fabricated on a nonconductive, heat tolerant sheet with sufficient room to apply EVA, rubber, or combinations thereof to the surface. The sheet can then be heat sealed to any relatively transparent, impact resistant, and able to with stand environmental damage such as moisture penetration, physical impact, extremes in temperature, etc.

Nanoporous structures of certain metal oxides can be obtained with the metal anodization process instead of, or as a variation of, the method illustrated in FIGS. 5A-5H. Among other systems, Al, Ti, and transparent conductive oxides can be anodically oxidized to form a regular nanopore structure, according to one embodiment.

In one experiment, tin oxide was anodized. Before electro deposition, a thin Au film was sputtered on one side of the aluminum anodically oxidized (AAO) membrane to serve as the conductive layer. Electro deposition of Sn into the pores of the AAO membrane was carried out at a constant current density of 0.75 mA/cm² for 1 hour in electrolyte containing sodium tricitrate of 25 g/L and tin dichloride of 7 g/L. The Sn embedded in the AAO membrane was anodized at 10 V in 0.2 M boric acid, whose pH value was adjusted to 8.6 by 0.5 M NaOH(aq). The anodization proceeded until the current density dropped to almost zero. The AAO membrane was then removed through wet etching with 0.5 M NaOH(aq), leaving behind an array of nanoporous tin oxide nanorods. Finally, the samples were calcinated at 500° C. for 3 hours in air.

The bristles 20 may be shaped to increase the surface area. For example, the bristles 20 may have “branches” or holes in the nanocable. Holes may be created by depositing the Cd/Au alloy as just described and anodizing.

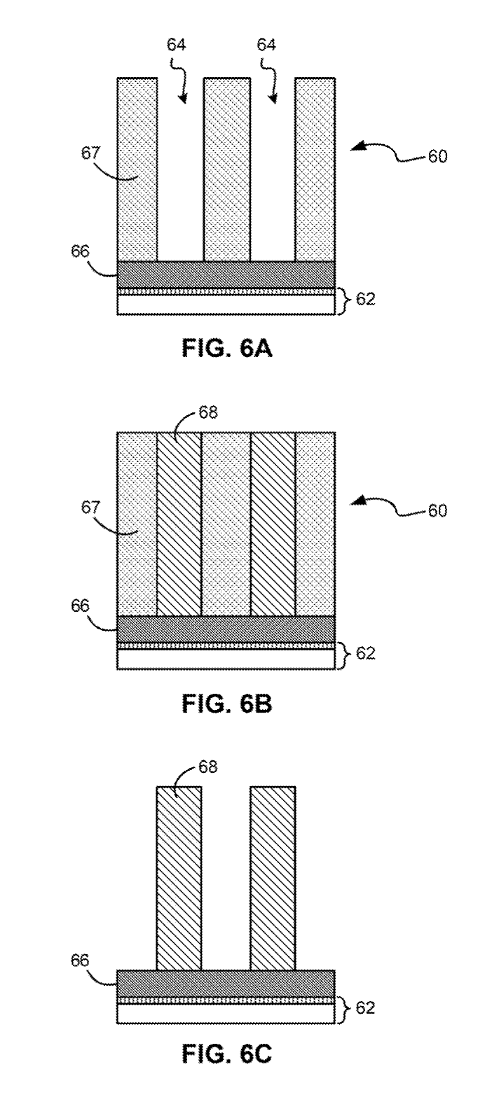

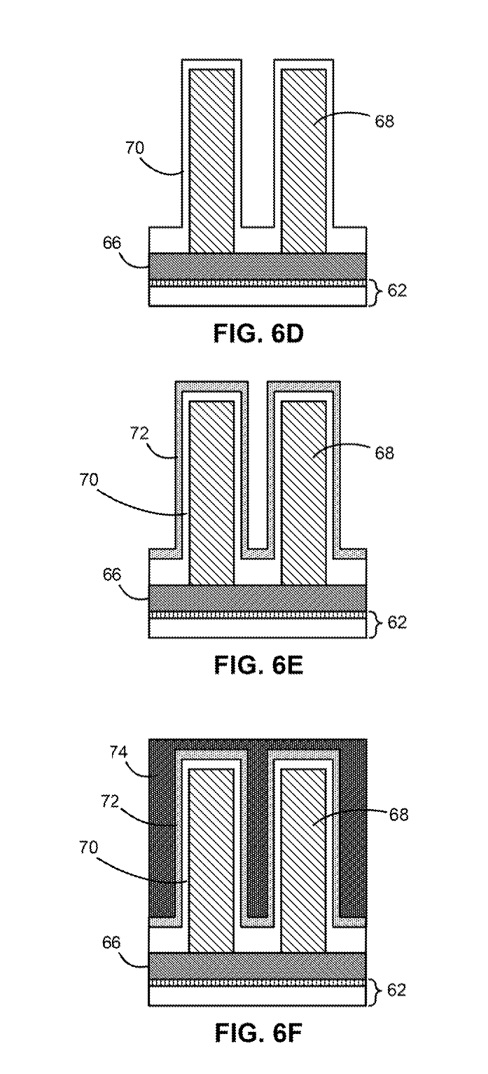

As another alternative to the method of FIGS. 5A-5H, the solar brush 10 may be prepared using a reverse-nanocable fabrication method that is illustrated in FIGS. 6A-6F, according to one embodiment, where the nanocable is formed as one of the last steps. In the reverse-fabrication method, the nanocables are prepared after one of the conductive layers, unlike in the method of FIGS. 5A-5H. Titanium isopropoxide may be used as the precursor molecule for the sol-gel preparation of the TiO₂ nanostructures.

To create an insulating layer in between nanocables, the top metal contact 74 can be removed to expose the composite surface made of conductive nanowire and p layer. Then, the p layer and n layer can be selectively etched leaving the conductive nanowires sticking out the top surface. Then, an insulating layer can be applied and the surface is then polished to result in a composite surface made of conductive nanowires and insulating layer. Then, a conductive layer is applied which will create the contact with the nanowires.

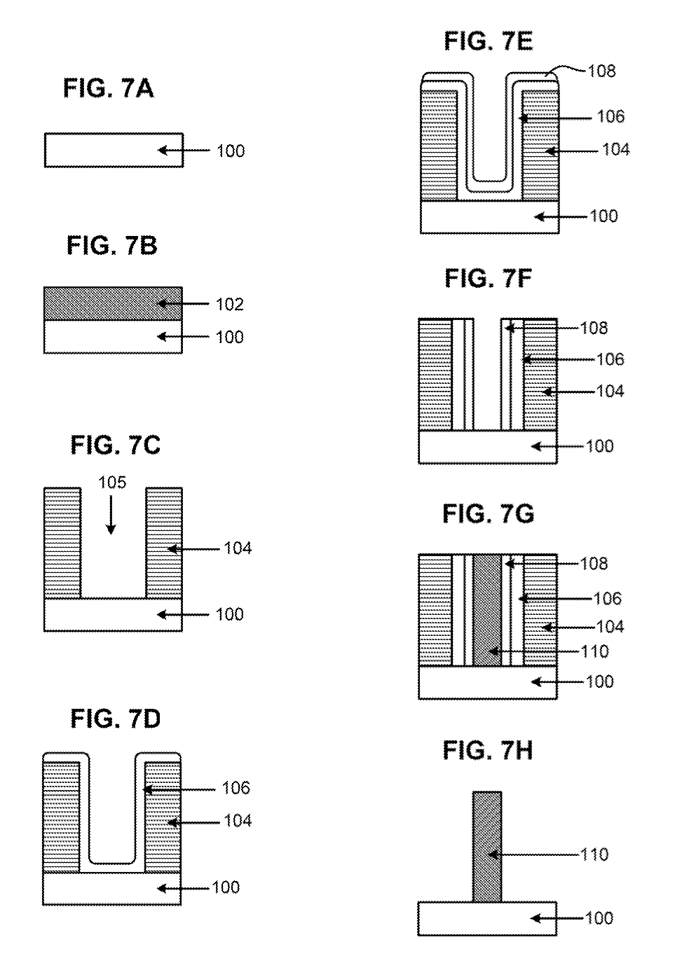

As shown in FIG. 7F, the polymer thin films 106, 108 on the top of the membrane and the base of the pore are removed, according to one embodiment. Next, electroless or electrochemical deposition of metal can take place inside of the pore 105 (FIG. 7G). A solvent extraction removes the polymer thin layers 106, 108 and a NaOH extraction removes the metal oxide template 104 to leave a precisely designed nanocable (FIG. 7H). Polymers such as poly(3-hexylthiophene) (P3HT), poly[2-methoxy,5-(2-ethyl-hexyloxy)-p-phenylene-vinylene] (MEH-PPV), poly (phenylene vinylene) (PPV), polyaniline, etc., may be used as the polymer thin layers 106, 108. Additionally, any suitable polymer from the Handbook of Conductive Polymers I by T. A. Skatherin or the Handbook of Polymer Coatings for Electronics Chemistry by J. J. Licari and L. A. Hughes may be used.

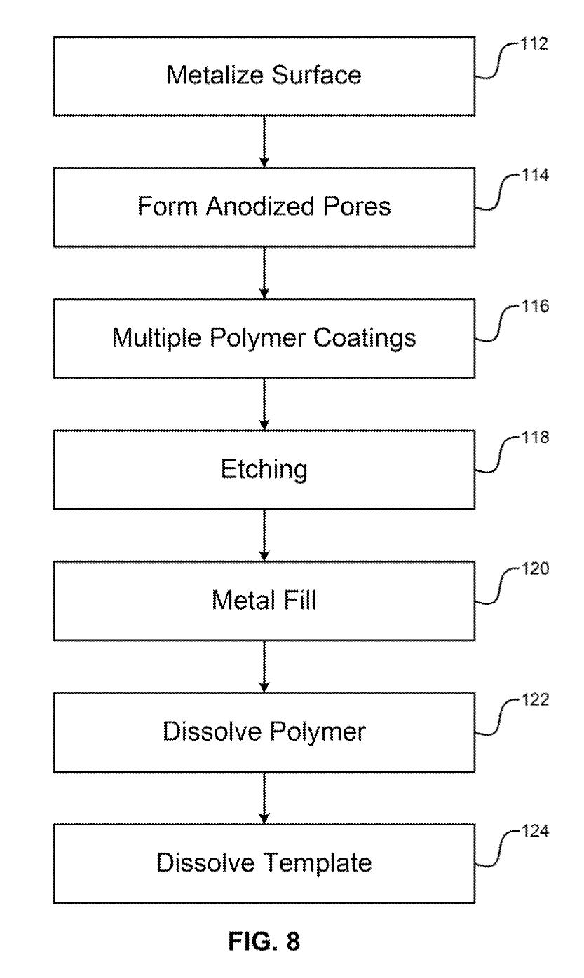

FIG. 8 is a flowchart summarizing the steps of the nanocable formation process illustrated in FIGS. 7A-7H, according to one embodiment. First, the substrate 100 is metalized (step 112) by deposition of a conductive material 102 on its surface. A membrane (a template) 104 is formed on the metalized substrate, and the membrane has a pore 105 of the desired size and shape that is anodized (step 114). One or more polymer layers 106, 108 are deposited and cured (step 116). The polymer layers on horizontal surfaces, such as the top of the template and the base of the pore, are removed by reactive ion etching (step 118). The pore is filled with a core metal 110 such as gold, copper, etc. (step 120). Then, the polymer layers are dissolved (step 122) and the membrane is removed by solvent extraction (step 124).

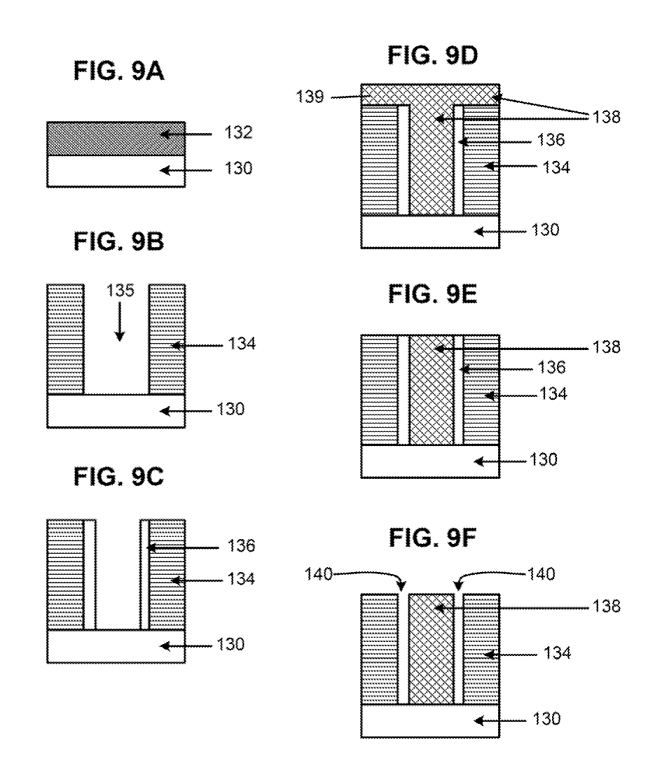

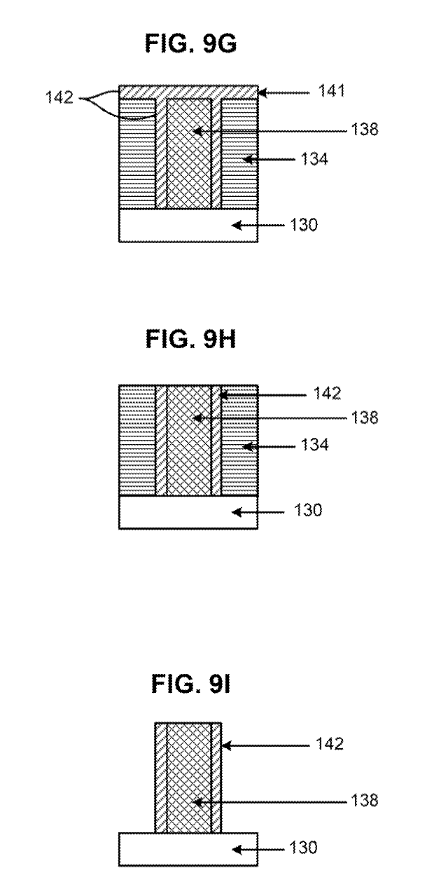

FIGS. 9A-9I illustrate that organic nanocables may be produced using a carbon jacket process, according to one embodiment. FIG. 9A shows a substrate 130 with a conductive layer 132 deposited on its surface. A metal oxide membrane 134 is formed, wherein the membrane has a pore 135 of the desired shape and size (FIG. 9B). As shown in FIG. 9C, carbon nanotubes 136 are formed on the inner wall of the pore 135, and titanium dioxide 138 is used to fill the remaining core portion of the pore 135 (FIG. 9D). As shown, titanium dioxide 138 fills the pore 135 and “overflows” to form a cap 139 above the carbon nanotube 136 and the metal oxide membrane 134. The cap 139 of the titanium dioxide 138 is removed in FIG. 9E, for example by any suitable etching method such as concentrated H₂SO₄ etch.

With the titanium dioxide cap 139 removed, the carbon nanotube 136 is burned off by exposure to air at about 600° C. (FIG. 9F), forming a gap 140 between the titanium dioxide core 138 and the metal oxide membrane 134, according to one embodiment. An organic Grätzel dye 142 is then deposited to fill the gap 140 and form an organic cap 141 (FIG. 9G). Polymers such as poly(3-hexylthiophene) (P3HT), poly[2-methoxy,5-(2-ethyl-hexyloxy)-p-phenylene-vinylene] (MEH-PPV), poly (phenylene vinylene) (PPV), and polyaniline, or any other suitable polymers from Handbook of Conductive Polymers I may be used with the Grätzel dye 142 as conductors. The organic Grätzel dye 142 can be sprayed with an inkjet printer, applied with a rotogravure process, sprayed on and wiped with a doctor blade, etc. The most suitable applications leave the minimum organic cap 141. Following this preliminary removal, the organic cap 141 may be etched (e.g., with RIE) or removed with a solvent wash to complete the removal process (FIG. 9H). Then, the metal oxide membrane 134 is removed, for example by wet etching with a carefully selected etchant (e.g., NaOH) that preferentially removes the metal oxide over titanium dioxide (FIG. 9I). In some embodiments, the metal oxide membrane 134 is made to be transparent so that its removal is not needed.

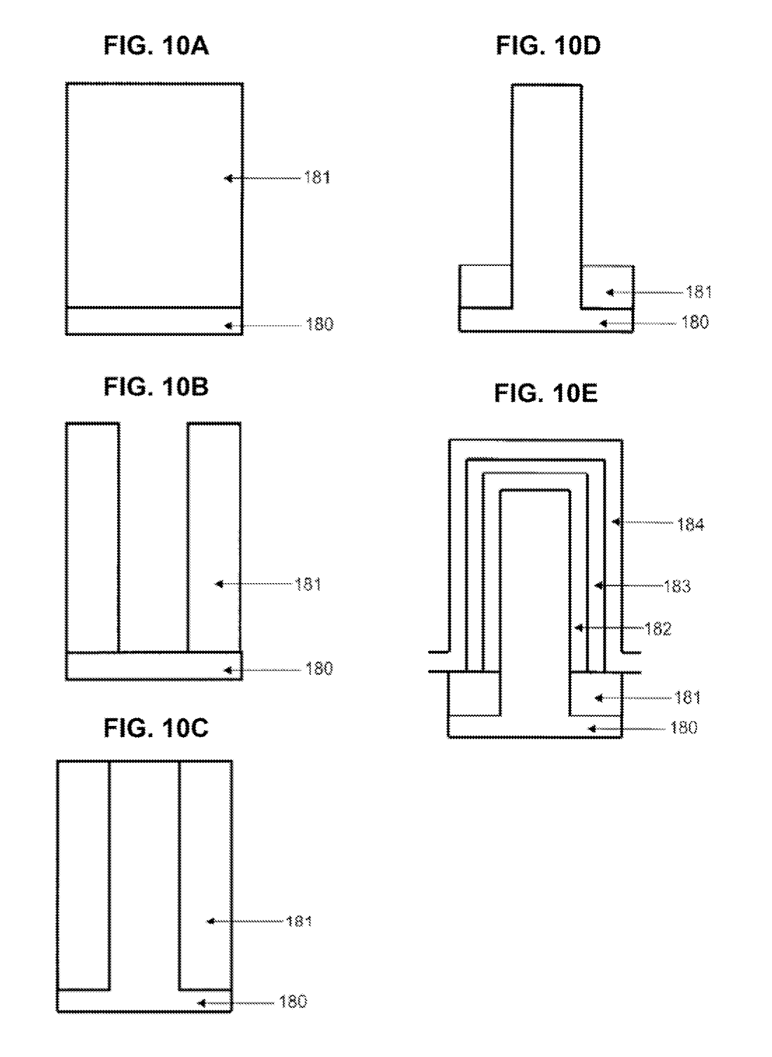

FIG. 10A shows an insulator 181 deposited on a conductor 180, according to one embodiment. The insulator can be any insulating material such as metal oxide, silicon dioxide, polymer, etc. The insulator may be applied through CVD, sputtered, etc. It can also be anodically grown from metal deposited on the conductor 181. FIG. 10B shows how the insulator can be wet or dry etched to form a pore that continues through to the conductor 180. FIG. 10C shows that the conductor can then be deposited through electroplating or the electroless deposition methods contained herein, according to some embodiments. FIG. 10D shows the conductor partially etched, according to one embodiment. In the case of silicon dioxide, a KOH solution can be used for etching, in the case of polymers, dichloromethane may be used. FIG. 10E shows the completed nanocable with the p-conductor 180, the insulator 181, the p-layer 182, the n-layer 183, and the TCO 184, according to one embodiment.

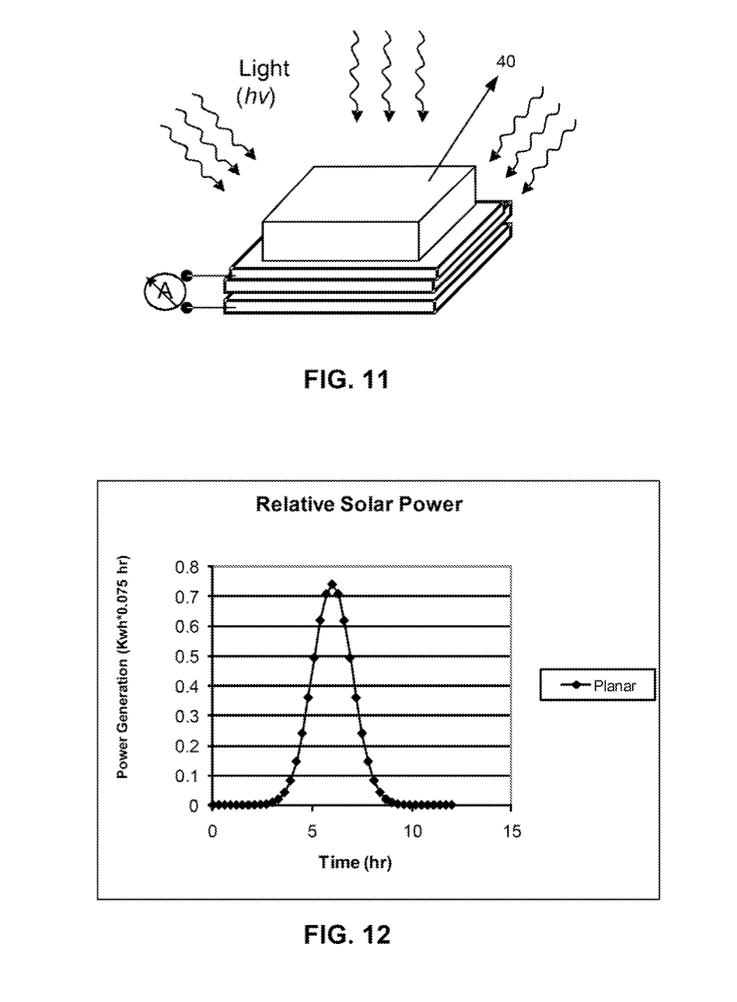

FIG. 11 shows the solar brush 10 encapsulated in an optical casing 40 for protection from various environmental elements, according to one embodiment. The optical casing 40 may also he made of a transparent polymer. The optical casing 40 may be made of film conductive oxides that allow light in but minimize soil and moisture contamination. Common materials for this application include Sn doped Sn₂O₂, Sn doped In₂O₃, ZnSnO₃, B doped ZnO. F doped In₂O₃, F doped SnO₂, F doped Cd₂SnO₄, F doped ZnO, TiN, Ag,Cd₂SnO₄, Ge doped In₂O₃, Ge doped SnO₂, Ge doped Zn₂SnO₄, ZnO/CdS, ZnO/ZnSe (for CdTE and CuInSe₂), ZnO/InₓSe_{y} (for CdTE and CuInSe₂), SnO₂/glass, ZnO/CdS, Cd₂SnO₄/Zn₂SnO₄, Zn(Se, OH), Zn(Se,O), Cd₂SnO₄/Zn₂SnO₄, etc. For additional conductivity, small wires or metal strips or thin bands of metalized glass can be added for additional conductivity, according to one embodiment. Metal may be minimized to reduce reflection but still be sufficient for adequate conduction of electricity, according to one embodiment. Traditional casings of low-iron glass and extruded aluminum may also be used as in the case of creating a module.

As mentioned above, there are numerous advantages of the solar brush 10 over conventional PV cells. The solar brush 10 demonstrates a high thermal stability. Unlike nanoparticles, where the linear thermal expansion coefficient increases with the reduction of the average grain size (Cu, for instance), Cu nano-wires show a smaller thermal expansion coefficient than that of the bulk Cu. The high thermal stability is related to the grain boundary structure and high aspect ratio of the nanostructure.

Daisy chain connections may also combat potential thermal expansion/contraction issues by minimizing chip size and then connecting them opposed to having a large sheet that would have a higher potential for stress cracking due to thermal expansion contraction. Daisy chains between cells may also add flexibility to a PV brush array. To accomplish this, the cells may have special interlocking mechanism to serve the dual purpose of a being a robust carrier of the film during processing and to speed assembly.

Because the method describes growth of conductors on a conductive sheet, the failure rate that plagues current PV cell manufacturing will be greatly improved giving further cost/efficiency advantages.

A further advantage of the PV brush is that the distance electrons diffuse through the semiconductive layer to the conductive layer is shorter than that of conventional PV cells thereby reducing internal resistance of the PV cells to deliver further power generation efficiencies, according to one embodiment. Because the PV bristles are thin, they use a small fraction of the material required for planar cells. A variety of organic and inorganic semiconductors can he applied to the conductive core and thicknesses can easily be optimized for power generation and stability.

Besides solar panels, nanoelectronic assemblies can also be used for light generation in optical chips, according to one embodiment. Optical chips are widely thought to be the replacement for semiconductor chips. Optical chips have narrow pathways that light can travel unhindered while semiconductor chips are limited by electric field effects between on circuit and the next. A micro light source with unique color attributes may be used in optical chip technologies. The nanoelectric assemblies may also be used as a nanolight source for such chips. Additionally, the nanodiodes can be used in a flat screen display for an ultra sharp video monitor. Additionally, the nanodiodes can be used for very energy efficient lighting.

The PV brush has flexible manufacturing options including membrane manufacturing technologies or photolithography e-beam, low density layered mechanical scoring, nanoporous templated, electroplating, and electrical arcing. These manufacturing methods may be used on a variety of membrane/nanoporous media which allows cell to be shaped and hardened to geometry that has maximum solar efficiency, maximum aerodynamic efficiency, maximum aesthetic appeal or a combination of the aforementioned attributes. Flexible units can also be achieved by daisy chain connection between small rigid units or from the use of a flexible substrate, according to one embodiment. At high temperatures, uneven thermal expansion can cause cracking and wear as well. High temperature degradation is mitigated because each component of this PV cell can be sized to minimize thermal expansion and can be further optimized with flexible expansion joint conductive connections between PV arrays. Additionally, the greater surface area of the solar brush will reduce thermal heat generated under the PV solar cell compared to the conventional flat unit which may greatly reduce unwanted heat buildup. One further advantage is that micro conductors often have reduced resistance at higher temperatures; therefore, the PV brush may be able to transfer energy more effectively than conventional PV cells at higher operating temperatures.

Finally, the geometry can be used to trap or release heat, according to one embodiment. If heat were found to be detrimental to energy above a certain point, the unit may be designed with vents. However, it should be noted that performance of nanocables may be different that than large scale wires. While large scale wires/cables have higher resistance to electrical flow at high temperatures, energy flow may improve due to improved flow through grain boundaries in nano-scale structures.

Power generation is a function of average power per day. The median sun hours for various cities in California is about 6.18 kW/(day*m²) according to a Go Solar® Company web page at www.solarexpert.com/Pvinsolation.html. On average, solar energy is drawn from about 6 hours per day based on the data made publicly available by National Renewable Energy laboratory findings. The distribution is commonly given as a Gaussian curve, which has the following distribution:

$$f ( x ) = \frac{{e}^{( \frac{- {( x - μ )}^{2}}{2 σ} )}}{σ \sqrt{2 π}}$$

Assuming an average of μ=6 hours, a standard deviation of σ=1 hour, and integrated power of 6.18 kwh/m² for an average day gives a maximum energy. When x=μ, the theoretical maximum power generated is about 4.933 kWhr/m². Based on EU studies of layering, the importance of having each solar event near the p-n junction, and reduced hot spots, the CdTe system may approach its theoretical efficiency limit. Efficiency could get as high as 30% or more with the single layer systems and potentially higher, especially if a high and low band gap system (discussed earlier) are combined. The distributions are shown in FIG. 12.

The power calculation works out as follows:

P=6.18 kWh/(m²×d) from the mean values for a California city

P_{Brush}=P×E×O

Thus, where E=29 (29% efficiency) for a CdTe/CdS PV cell and O=the orientation gain 1.44 (44% gain), P_{Brush}=2.60 kWhr/(m²×d) (average day in the mean city in CA).

However, it should be noted that the brush can pick up about a 44.8% gain in efficiency by because it would require little if any sun orientation adjustments. The orientation of the solar brush 10 may have a large effect on performance. Planar PV modules lose up to 44% power from poor orientation and often need to be reoriented using a “solar compass”. Due to its unique design, the solar brush 10 does not require reorientation.

If electrical current through the PV device is sufficiently high, a cooling systems that may either be used to generated thermoelectric power (i.e. steam turbine type of power generation) or water heating systems for home use may also be possible.

A majority of the light from the sun is scattered from the atmosphere. Collecting scattered light using the solar brush 10 should lead to even higher energy production. Further energy gains from multi-junction solar cells may bump the efficiency to double what is believed to be currently possible.

The solar brush 10 will probably approach the theoretical maximum efficiency for a given material. Because the brush can be made nearly transparent, most of the light continues to travel through the cell. For practical purposes, the brush would appear to be of ∞ thickness. Because the bristles can be designed just thick enough for stable solar absorption, each absorptive event would happen near the p-n junction. The occurrence of the absorptive event near the p-n junction improves cell efficiency. Another key to improving cell efficiency is to reduce localized heating. Each time there is solar absorption, part of the energy ejects the electron and part of the energy heats the cell. The heating reduces the efficiency of the cell. When cells rely on back reflection, they are also doubling the heat load for a given areas. As the sun moves across the sky, the penetration angle is changing and the trajectory of the solar stream is changing so there is a greater quantity of “fresh” material for the photons to impact. With the solar brush 10, more of the absorption events can be made to occur near the p-n junction through control of the layer thicknesses, and the light stream will pass through greater amounts of PV material. Multiple junction material is believed to be the key to maximum efficiency in the future. Table 2 shows efficiency potential, band gap, and field efficiencies for several materials, any of which may be used in an embodiment of the present invention.

TABLE 2
Efficiencies of photovoltaic material

| | Theoretical | Laboratory | | |
|---|---|---|---|---|
| | Maximum | Maximum | Field | Band |
| Material | Efficiency (%) | Efficiency (%) | Efficiency (%) | Gap (eV) |
| Single Crystal SI | 27 | 23.5 | 14.0-17.0 | 1.1 |
| Si HIT single crystal | 27 | 21.0 | 15.5-16.5 | 1.1 |
| Si Poly Crystal | 27 | 20.0 | 11.5-14.2 | 1.1 |
| Si Ribbon | 27 | 17 | 11.0-13.0 | 1.1 |
| ClS | 24 | 18 | 9.0-11.5 | 0.9 |
| GaAs | 30 | | | 1.4 |
| CdTe | 29 | 17 | 8.0-10.0 | 1.5 |
| Amorphous Si | 25 | 13.0 | 5.0-9.5 | 1.7 |
| Indium Gallium Nitride | 31* | 17 | 8.5-11.05 | 0.8 |
| Graetzel | 20* | 10.9 | 45 | |
| Polymer | 9* | 4.9 | 1.0-2.5 | |

*indicates that the value is an estimate.

Efficiency compares favorably with current technologies to give the maximum power increases. Table 3 shows the potential energy efficiency and power generation capability in the state of California.

TABLE 3
Potential energy efficiency and power generation in California

| Material | Efficiency | kW * hr/Day/m² |
|---|---|---|
| PV Brush (CdTe) | ~ 29 | 2.60 |
| Single Crystal Si | 17 | 1.19 |
| Polymer | 2.0 | 0.11 |

Power generation and effective areas for the brush can be significantly boosted through the use of a solar concentrator. A solar concentrator may redirect large areas of light perpendicular to the surface, thereby utilizing the surface area at the depths of the brush. Only light angles close to 90° can penetrate a high area shell. The penetration depth in shown by FIG. 1 is the spacing distance between bristles times tan Θ. As Θ approaches 90°, tan Θ approaches ∞ and the required penetration level is achieved. The effective area of the solar cell is calculated by dividing the penetration dept by the bristle height and multiplying it by the area. The power output of a high efficiency, high area solar cell in one embodiment is between 50 and 285 kW/day/m² with a solar concentrator. The output ranges compare favorably with the maximum output of 0.94 kW/day/m² based on the best known field results ever for single silicon PV arrays that are produced with a process which is probably much more costly than the methods and structures presented herein.

Konarka uses a technology where printed polymers generate energy from all visible spectra. As described in http://www.konarkatech.com/about/, PV polymers are printed on polymer sheets. Materials are produced by injecting a dye into titanium dioxide and printing the material on to polymers. The Konarka technology is expected to yield 10% efficiency and last about 8 years. In comparison, the materials disclosed herein that are used for the solar brush 10 have a lifespan in the 25 to 30 year time frame. Konarka's process may be 100 times less expensive than the solar brush 10 but produces PV cells of only around 2% efficiency. Furthermore, these PV cells would not have a form that is compatible with concentrators. Therefore, the maximum power Konarka's PV film would expect to generate on a given day would be about 0.11 kW/m², and the brush may generate between 450 and 2500 times the power that the Konarka system generates.

Table 4 illustrates the power generation for 8″ disk PV cells.

TABLE 4
High efficiency solar cell power generation for 8″ disk PV cells.

| | | | | Estimated High |
|---|---|---|---|---|
| | | | | Efficiency |
| Bristle | Bristle | | Area | Power |
| Height | Diameter | Cable Density | (m² · brush/m² | Generation |
| (μm) | (nm) | (#/m²) | planar) | (kWhr/m² * day) |
| 50 | 220 | 5 × 10¹² | 172.76 | 48.06 |
| 100 | 220 | 5 × 10¹² | 345.52 | 96.12 |
| 50 | 370 | 1 × 10¹² | 50.26 | 13.98 |
| 100 | 370 | 1 × 10¹² | 100.54 | 27.96 |

Solar brushes 10 may be made from disks of any commercially-available diameter, or can be grown from any dimension films using oxide templates, according to various embodiments. They can use existing photolithography and sputtering machines. If an 8″ diameter disk is used, it would generate the power equivalent of 0.97 to 5.58 m² planar photovoltaic cells. If a perfect reflector were used in the solar collector, the minimum dish size would range from a diameter of 1.1 m to 14.8 m for full utilization of the PV cell area. Because perfect reflectors do not exist, some of the energy would be lost to absorption and misdirected reflections. A 2 m to 25 m diameter may be used to generate the maximum energy. Smaller units can be produced if desired, the size being a function of the power requirements and the installation location. The 8″ disk may generate 1.6 to 24.42 kW/day depending on the final area and thickness of material on a disk. The system is also preferably sized to allow proper current conduction without undue system heating of the substrate metal.

The small disk size will allow easy cleaning and reduce efficiency losses over time. Since the area of the central disk is so small, it may be designed to snap in and out to be cleaned in a way that is impractical for larger cells.

The wide range of methods to form nanocables on either flexible or rigid substrate that is shaped to a given specification then hardened impacts the efficiency of the film.

Hard coatings such as TiN, ZrN, or HfN that have melting points around 3,000° C. may be used for certain layers to minimize reflectance or as a reinforcement “jacket” to increase the hardness of the nanocables.

One useful technique that allows improved geometric control of the brush is over etching the top or bottom of the template so that the top or bottom of the bristle curves or steps outward (away from its axis), thereby having a larger diameter towards one end thereof than the other. The increased diameter of some or all of the bristles towards the bottom of the array (substrate end) or top of the array may be effected in many other ways, such as selectively adding more material to the top or bottom portion of the bristle, plating in a bath only covering a portion of the bristle length, etc. The larger lower diameter may be only along a portion of the bristle, thereby creating a step in diameter change somewhere along the bristle's length, may be a gradual tapering of the outer surface, a tapered portion and one or more portions having a constant diameter along the axis of the bristle, etc. The larger diameter at the bottom of the bristle is useful for many reasons. For example, this geometry provides greater stability of the bristle (less likely to break off). This geometry allows bristles to be both taller and placed closer to each other while maintaining a uniform, continuous TCO coating. This geometry also enables many TCO deposition techniques to be effective. Illustrative TCO deposition techniques include spraying, dipping, spin-on application, etc.

In other approaches, where the nanocable is overplated to form a conductive layer above the template, as disclosed in U.S. Provisional Patent Application No. 61/310,227, filed Mar. 3, 2010, and which has been incorporated by reference, it may be beneficial to have the tapering located near the overplated area, the overplated area being the conductive substrate for subsequent processing.

TCO may also be applied in a heated liquid form. Accordingly, in one embodiment, the liquid is so hot that the TCO deposition and the heat activation of the cell are combined in one step. In other words, the heat from the TCO activates the PV cells.

Heat activation can also be performed with a laser. One preferred approach uses a pulsating laser, which affords good control over both the amount of energy applied to the array as well as allowing tailored activation of particular sections of the array. Another advantage of laser activation is that very little energy is wasted and the carbon footprint is minimized. Often modules are activated in ovens where most of the energy is lost to the environment. Another advantage is that the correct amount of energy is applied to the PV cell. When cells get to much or too little energy, the cell performance is reduced. Finally, the lasers can be pulsed such that some nanocables receive more energy than others. This can be particularly helpful when multiple materials with differing activation requirements are found in the PV array.

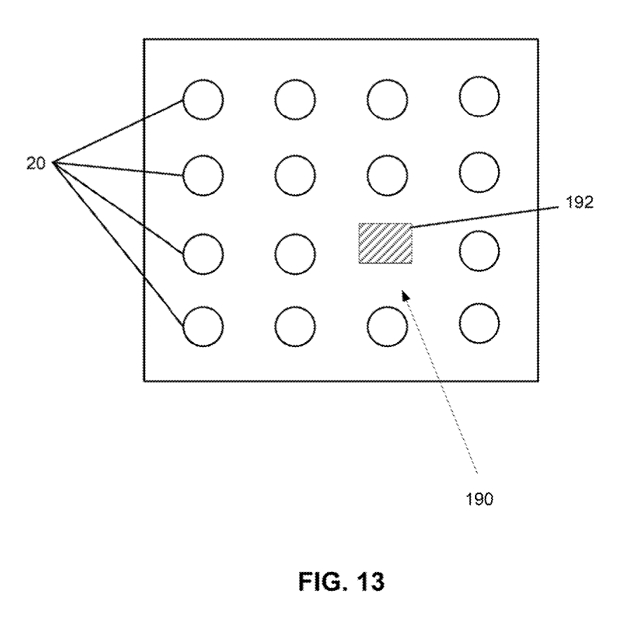

Arrays can be formed or patterned is such a way as to leave voids in the array where conductors can be placed in communication with the front contact layer to reduce the current load on the bulk of the front contact layer. Voids can be patterned also to allow control the voltage of the module. In one approach, assume the nanocables are about uniformly arranged in a two-dimensional array as in FIG. 4. Absence or removal of one or more of the bristles 20 would create a void 190 in the array, as shown in FIG. 13. Thus, a conductor 192 can be formed in the void, between the bristles surrounding the void. The number and position of the voids may he selected by the designer based on the foregoing or other criteria.

Additional techniques which may be used in portions of various embodiments are disclosed in copending U.S. patent application Ser. Nos. 11/466,411 and 11/466,416, both filed Aug. 22, 2006, and which are both incorporated by reference.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

What is claimed is:

1. A method, comprising:
adding a template to a substrate;
depositing conductive material in the template thereby forming an array of conductive nanocables on the substrate;
removing at least part of the template; and
depositing at least one layer of photovoltaic material on exposed portions of the conductive nanocables.

2. The method as recited in claim 1, wherein the template is created by forming a membrane on a patterned surface, and removing the membrane from the patterned surface, wherein the membrane is subsequently coupled to the substrate for being the template.

3. The method as recited in claim 2, wherein the membrane comprises a dielectric, polymer or a combination thereof.

4. The method as recited in claim 1, further comprising creating a front contact in communication with an uppermost of the at least one layer of photovoltaic material.

5. The method as recited in claim 1, further comprising depositing a layer over the nanocables, wherein a material of the layer is of sufficient temperature at deposition thereof to photovoltaically activate the nanocables with the at least one layer of photovoltaic material thereon.

6. The method as recited in claim 5, wherein the layer is a transparent conductive oxide that also acts as a front contact for the nanocables with photovoltaic material thereon.

7. The method as recited in claim 1, further comprising depositing a dielectric overcoat of ethyl vinyl acetate.

8. The method as recited in claim 1, wherein the depositing one of the layers of photovoltaic material includes performing multiple chemical bath depositions with at least one of a thermal anneal and a densification performed between the chemical bath depositions.

9. The method as recited in claim 1, wherein axes of the nanocables are tilted from a direction normal to a plane of the substrate.

10. The method as recited in claim 1, wherein the template partially remains during the deposition of the at least one layer of photovoltaic material.

11. The method as recited in claim 10, wherein at least a portion of the remaining template is an insulating layer.

12. The method as recited in claim 1, wherein the substrate is electrically conductive, and further comprising segmenting at least a portion of the conductive substrate for forming electrically isolated segments thereof.

13. The method as recited in claim 12, wherein in a first deposition, electricity is conducted only to a first group of the conductive nanocables for depositing the at least one layer of photovoltaic material thereon; wherein in a second deposition, electricity is conducted only to a second group of the conductive nanocables for depositing the at least one layer of photovoltaic material thereon; wherein the first and second groups include at least some different conductive nanocables.

14. The method as recited in claim 13, wherein a composition, thickness, and/or height of structures formed by the first deposition is different than a composition, thickness, and/or height of structures formed in the second deposition.

15. The method as recited in claim 1, further comprising forming a conductive layer over the at least one layer of photovoltaic material, and segmenting the conductive layer for forming electrically isolated segments thereof.

16. The method as recited in claim 1, further comprising coupling the array of conductive nanocables with photovoltaic material thereon to a photovoltaic device, the photovoltaic device being at least semi-transparent, wherein the array is positioned relative to the photovoltaic device such that light passing through the photovoltaic device strikes the array.

17. The method as recited in claim 1, wherein at least some of the conductive nanocables with photovoltaic material thereon have a portion with a wider diameter than in another portion thereof.

18. The method as recited in claim 17, wherein the portion having the wider diameter is positioned towards the substrate.

19. The method as recited in claim 17, wherein the portion having the wider diameter is positioned away from the substrate.

20. The method as recited in claim 1, wherein the template is formed by embossing.

21. The method as recited in claim 1, further comprising photovoltaically activating the conductive nanocables with photovoltaic material thereon using a pulsating laser.

22. The method as recited in claim 1, wherein the template is added to the substrate in a continuous process.

23. The method as recited in claim 1, wherein the substrate is conductive, and further comprising treating the substrate for enhancing electrical contact between the substrate and the conductive nanocables.

24. The method as recited in claim 1, wherein voids are present in the array, and further comprising forming a conductive layer over the array and coupling a conductor to the conductive layer adjacent the void.

25. The method as recited in claim 1, wherein the template is formed at least in part from a photoresist that is patterned without a hard mask.

26. The method as recited in claim 1, wherein the at least one layer of photovoltaic material is electroplated.

27. The method as recited in claim 1, wherein the at least one layer of photovoltaic material is formed by chemical vapor deposition and etching.

28. A nanostructure, comprising:
an array of nanocables extending from a substrate, the array of nanocables having physical characteristics of having been formed using an at least partially removed template;
an insulating layer extending along the substrate; and
at least one layer of photovoltaic material overlaying portions of the nanocables.

29. The nanostructure as recited in claim 28, wherein the nanocables are elongated.

30. The nanostructure as recited in claim 28, wherein the nanocables have substantially uniform peripheries.

31. The nanostructure as recited in claim 28, wherein the template is a membrane.

32. The nanostructure as recited in claim 28, wherein the nanocables are tilted from normal to a plane of the substrate.

33. The nanostructure as recited in claim 28, wherein a portion of the template remains, the portion of the template being an insulating layer between the nanocables.

34. The nanostructure as recited in claim 28, further comprising a front contact in communication with an uppermost of the at least one layer of photovoltaic material.

35. The nanostructure as recited in claim 28, further comprising a dielectric overcoat of ethyl vinyl acetate.

36. The nanostructure as recited in claim 28, wherein the at least one of the layer of photovoltaic material has a physical structure characteristic of formation thereof by multiple chemical bath depositions with at least one of a thermal anneal and a densification performed between the chemical bath depositions.

37. The nanostructure as recited in claim 28, wherein the substrate is electrically conductive, and wherein at least a portion of the conductive substrate is segmented into electrically isolated segments.

38. The nanostructure as recited in claim 28, further comprising a conductive layer over the at least one layer of photovoltaic material, the conductive layer being segmented into electrically isolated segments.

39. The nanostructure as recited in claim 28, wherein a first group of the nanocables has a different composition, thickness, and/or height than a second group of the nanocables.

40. The nanostructure as recited in claim 28, wherein the at least one layer of photovoltaic material overlaying a first group of the nanocables has a different composition and/or thickness than the at least one layer of photovoltaic material overlaying a second group of the nanocables.

41. The nanostructure as recited in claim 28, further comprising a photovoltaic device coupled to the array of nanocables, the photovoltaic device being at least semi-transparent, wherein the array is positioned relative to the photovoltaic device such that light passing through the photovoltaic device strikes the array.

42. The nanostructure as recited in claim 28, wherein at least some of the conductive nanocables with photovoltaic material thereon have a portion with a wider diameter than in another portion thereof.

43. The nanostructure as recited in claim 42, wherein the portion having the wider diameter is positioned towards the substrate.

44. The nanostructure as recited in claim 42, wherein the portion having the wider diameter is positioned away from the substrate.

45. The nanostructure as recited in claim 28, wherein the substrate is conductive, wherein the substrate has physical characteristics of being treated for enhancing electrical contact between the substrate and the conductive nanocables.

46. The nanostructure as recited in claim 28, wherein at least one void is present in the array.

47. The nanostructure as recited in claim 46, further comprising a conductive layer over the array and a conductor coupled to the conductive layer in the void.

48. The nanostructure as recited in claim 28, further comprising a conductive grid above the insulating layer and between the nanocables.
